(19) United States
(12) Patent Application Publication
(10) Pub. No.: US 2026/0344145 A1
(43) Pub. Date: Oct. 29, 2026

(54) DISPLAY DEVICE AND DISPLAY PANEL

(71) Applicant: LG Display Co., Ltd., Seoul (KR)

(72) Inventor: SangHoon Lee, Seoul (KR)

(73) Assignee: LG Display Co., Ltd., Seoul (KR)

(21) Appl. No.: 19/637,672

(22) Filed: Apr. 2, 2026

(30) Foreign Application Priority Data
Apr. 24, 2025 (KR) 10-2025-0053732

(51) Int. Cl. H10H 29/39; H10H 29/41

(52) U.S. Cl. CPC H10H 29/39; H10H 29/41

(57) ABSTRACT

A display device and a display panel include a substrate, a plurality of light emitting elements which is disposed on the substrate and each includes a first electrode and a second electrode, a first planarization layer which is disposed on the substrate so as to surround a part of side surfaces of the plurality of light emitting elements, a first connection electrode which is disposed on the first planarization layer and is connected to the first connection electrode, a passivation layer disposed on the first connection electrode, a part of the passivation layer, a second planarization layer disposed on the first planarization layer and the first connection electrode, and a second connection electrode which is disposed on the second planarization layer and is connected to the second electrode, wherein the passivation layer exposes an end of the first connection electrode. Therefore, the short defect may be minimized or reduced.

### CROSS-REFERENCE TO RELATED APPLICATIONS

This application claims the priority and benefit of Korean Patent Application No. 10-2025-0053732 filed on Apr. 24, 2025, in the Korean Intellectual Property Office, the entire contents of which are hereby expressly incorporated for all purposes.

### BACKGROUND

### Technical Field

The present disclosure relates to a display device, and more particularly, to a display device and a display panel in which a short defect between electrodes is minimized or reduced.

### Discussion of the Related Art

Display devices used for a monitor of a computer, a TV, or a mobile phone include an organic light emitting display (OLED) that emits light by itself, and a liquid crystal display (LCD) that comprises a separate light source.

Display devices have been applied in a variety of applications, including computer monitors and TVs as well as personal portable devices, and research is being conducted on display devices that have a large display area and have a reduced volume and weight.

In addition, recently, a display device including a light emitting diode (LED) has attracted attention as a next-generation display device. Since the LED is made of an inorganic material rather than an organic material, reliability is high, and a lifespan thereof is longer than that of a liquid crystal display device or an organic light emitting display device. Further, the LED has a fast lighting speed, high luminous efficiency, and a strong impact resistance so that a stability is high and an image having a high luminance can be displayed.

The description provided in the description of the related art section should not be assumed to be prior art merely because it is mentioned in or associated with the description of the related art section. The description of the related art section may include information that describes one or more aspects of the subject technology, and the description in this section does not limit the disclosure.

### SUMMARY

Accordingly, the present disclosure is directed to a display device and a device panel that substantially obviate one or more problems due to limitations and disadvantages of the related art. For example, a connection defect between electrodes may occur in a display device in related art. An object of the present disclosure includes providing a display device capable of self-alignment of a connection electrode and a light emitting element.

An object of the present disclosure also includes, for example, a display device in which a short defect between connection electrodes is minimized or reduced.

An object of the present disclosure also includes, for example, a display device which suppresses a short defect to be driven with a low power in terms of reducing power consumption.

Objects of the present disclosure are not limited to the above-mentioned objects, and other objects, which are not mentioned above, can be clearly understood by those skilled in the art from the following descriptions.

To achieve these objects and other advantages of the present disclosure, as embodied and broadly described herein, a display device according to an example embodiment of the present disclosure includes a substrate in which a plurality of sub pixels are defined, a plurality of light emitting elements which are disposed on the substrate in the plurality of sub pixels and each includes a first electrode and a second electrode, a first planarization layer which is disposed on the substrate so as to surround a part of side surfaces of the plurality of light emitting elements, a first connection electrode which is disposed on the first planarization layer and is electrically connected to the first connection electrode, a passivation layer disposed on the first connection electrode, a part of the passivation layer, a second planarization layer disposed on the first planarization layer and the first connection electrode, and a second connection electrode which is disposed on the second planarization layer and is electrically connected to the second electrode, wherein the passivation layer exposes an end of the first connection electrode. Therefore, the short defect may be minimized or reduced.

According to another example embodiment of the present disclosure, a display device includes a substrate in which a plurality of sub pixels are defined; a plurality of light emitting elements which are disposed on the substrate in the plurality of sub pixels and includes a first electrode and a second electrode disposed at a position higher than the first electrode; a first planarization layer which is disposed on the substrate so as to surround a part of side surfaces of the plurality of light emitting elements; a first connection electrode which is disposed on the first planarization layer and is electrically connected to the first electrode; a second planarization layer disposed on the first planarization layer and the first connection electrode; and a second connection electrode which is disposed on the second planarization layer and is electrically connected to the second electrode.

According to another example embodiment of the present disclosure, a display device includes a substrate in which a plurality of sub pixels are defined; a plurality of light emitting elements which are disposed on the substrate in the plurality of sub pixels and each includes a first electrode and a second electrode; a first planarization layer which is disposed on the substrate so as to surround a part of side surfaces of the plurality of light emitting elements; a first connection electrode which is disposed on the first planarization layer and is electrically connected to the first electrode; a passivation layer which is disposed on the first connection electrode; a second planarization layer which is disposed on the first planarization layer, the first connection electrode, and at least a part of the passivation layer; and a second connection electrode which is disposed on the second planarization layer and is electrically connected to the second electrode, wherein the passivation layer exposes an end of the first connection electrode, wherein the plurality of sub pixels includes a first sub pixel and a second sub pixel disposed in different area of the substrate and wherein a height of an uppermost end of the second planarization layer disposed in the second sub pixel is lower than a height of an uppermost end of the second planarization layer disposed in the first sub pixel.

According to another example embodiment of the present disclosure, a display panel includes a substrate in which a plurality of sub pixels are defined; a plurality of light emitting elements which are disposed on the substrate in the plurality of sub pixels and each includes a first electrode and a second electrode; a first planarization layer which is disposed on the substrate so as to surround a part of side surfaces of the plurality of light emitting elements; a first connection electrode which is disposed on the first planarization layer and is electrically connected to the first electrode; a passivation layer which is disposed on the first connection electrode; a second planarization layer which is disposed on the first planarization layer, the first connection electrode, and a part of the passivation layer; and a second connection electrode which is disposed on the second planarization layer and is electrically connected to the second electrode, wherein the passivation layer exposes an end of the first connection electrode.

According to another example embodiment of the present disclosure, a display panel includes a substrate in which a plurality of sub pixels are defined; a plurality of light emitting elements which are disposed on the substrate in the plurality of sub pixels and includes a first electrode and a second electrode disposed at a position higher than the first electrode; a first planarization layer which is disposed on the substrate so as to surround a part of side surfaces of the plurality of light emitting elements; a first connection electrode which is disposed on the first planarization layer and is electrically connected to the first electrode; a second planarization layer disposed on the first planarization layer and the first connection electrode; and a second connection electrode which is disposed on the second planarization layer and is electrically connected to the second electrode.

According to another example embodiment of the present disclosure, a display panel includes a substrate in which a plurality of sub pixels are defined; a plurality of light emitting elements which are disposed on the substrate in the plurality of sub pixels and each includes a first electrode and a second electrode; a first planarization layer which is disposed on the substrate so as to surround a part of side surfaces of the plurality of light emitting elements; a first connection electrode which is disposed on the first planarization layer and is electrically connected to the first electrode; a passivation layer which is disposed on the first connection electrode; a second planarization layer which is disposed on the first planarization layer, the first connection electrode, and at least a part of the passivation layer; and a second connection electrode which is disposed on the second planarization layer and is electrically connected to the second electrode, wherein the passivation layer exposes an end of the first connection electrode, wherein the plurality of sub pixels includes a first sub pixel and a second sub pixel disposed in different area of the substrate and wherein a height of an uppermost end of the second planarization layer disposed in the second sub pixel is lower than a height of an uppermost end of the second planarization layer disposed in the first sub pixel.

Other detailed matters of the embodiments are included in the detailed description and the drawings.

According to the one or more example embodiments of the present disclosure, through the ashing process of the first planarization layer and the second planarization layer, the first connection electrode and the second connection electrode are connected to the light emitting element in a self-alignment manner without a separate alignment process, thereby securing a transfer margin.

According to the one or more example embodiments of the present disclosure, the passivation layer is disposed on the first connection electrode to separate the first connection electrode and the second connection electrode, thereby preventing or suppressing a short defect between the first connection electrode and the second connection electrode.

According to the one or more example embodiments of the present disclosure, a planarization layer fills a space between the passivation layer and the light emitting element to cover the first connection electrode exposed by the passivation layer, thereby preventing or suppressing a short defect in which the first connection electrode and the second connection electrode are connected by separating the first connection electrode and the second connection electrode.

According to the one or more example embodiments of the present disclosure, even though the planarization layer is disposed lower than the passivation layer disposed on the first connection electrode, the space between the passivation layer and the light emitting element is filled with an organic pattern to cover the first connection electrode exposed by the passivation layer, thereby separating the first connection electrode and the second connection electrode to prevent or suppress a short defect in which the first connection electrode and the second connection electrode are connected.

According to the one or more example embodiments of the present disclosure, a potential defect due to a short defect is minimized or reduced and a lifespan of the display device is improved, such that the display device may be driven with low power in terms of reducing power consumption.

The effects according to the present disclosure are not limited to the contents exemplified above, and more various effects are included in the present disclosure.

### BRIEF DESCRIPTION OF DRAWINGS

The accompanying drawings, which are included to provide a further understanding of the present disclosure and are incorporated in and constitute a part of this application, illustrate various example embodiments of the present disclosure and together with the description serve to explain various principles of the disclosure. In the drawings:

FIG. 1 is a schematic block diagram of a display device according to an example embodiment of the present disclosure.

FIG. 2A is a partial cross-sectional view of a display device according to an example embodiment of the present disclosure.

FIG. 2B is a perspective view of a tiling display device according to an example embodiment of the present disclosure.

FIG. 3 is a cross-sectional view of a display device according to an example embodiment of the present disclosure.

FIG. 4 is a cross-sectional view of a display device according to another example embodiment of the present disclosure.

FIGS. 5A to 5D are cross-sectional views for illustrating a process for a method of manufacturing a display device according to another example embodiment of the present disclosure.

FIG. 6 is a cross-sectional view of a display device according to still another example embodiment of the present disclosure.

FIG. 7 is a cross-sectional view of a display device according to still another example embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Hereinafter, example embodiments will be described in detail with reference to the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and characteristics of the present disclosure and a method of achieving the advantages and characteristics may be clear by referring to example embodiments described below in detail together with the accompanying drawings. However, the present disclosure is not limited to the example embodiments disclosed herein but may be implemented in various forms. The example embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers, and the like illustrated in the accompanying drawings for describing the example embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “include,” “have,” “comprise,” “contain,” “constitute,” “make up of,” “formed of,” and “consist of” used herein are generally intended to allow other components to be added unless the terms are used with the term “only”. Any references to singular may include plural, and vice versa, unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the a more specific term like “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for referring to one component separately from the other components. Therefore, a first component to be mentioned below may be a second component in a technical concept of the present disclosure.

Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can”.

The term “at least one” should be understood as including all possible combinations which can be suggested from one or more relevant items. For example, the meaning of “at least one of a first item, a second item, or a third item” may be each one of the first item, the second item, or the third item and also be all possible combinations that can be suggested from two or more of the first item, the second item, and the third item.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but example embodiments of the present disclosure are not limited thereto.

Like reference numerals generally denote like elements throughout the disclosure. In the specification, in adding reference numerals for elements in each drawing, it should be noted that like reference numerals already used to denote like elements in other drawings are used for elements wherever possible. In addition, the dimension scales of constituent elements shown in the drawings may be different from actual dimension scales, for convenience of description. That is, the dimension scales of constituent elements shown in the drawings should not be interpreted to be the same as those shown in the drawings.

The features of various example embodiments of the present disclosure can be partially or entirely adhered to or combined with each other and can be interlocked and operated in technically various ways, and the example embodiments can be carried out independently of or in association with each other.

Unless otherwise defined, all terms (including technical and scientific terms) used herein have the same meaning as commonly understood by one of ordinary skill in the art to which example embodiments belong. It may be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

Hereinafter, the present disclosure will be described in detail with reference to the drawings.

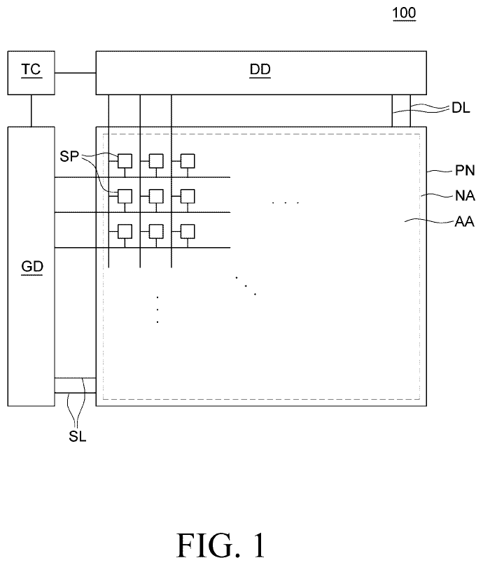

FIG. 1 is a schematic block diagram of a display device according to an example embodiment of the present disclosure. In FIG. 1, for the convenience of description, among various components of the display device 100, only a display panel PN, a gate driver GD, a data driver DD, and a timing controller TC are illustrated.

As shown in FIG. 1, a display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals provided from the timing controller TC. FIG. 1 illustrates that one gate driver GD is disposed to be spaced apart from one side of the display panel PN. However, the number and arrangement of the gate drivers GD are not limited thereto.

The data driver DD converts image data input from the timing controller TC into a data voltage using a reference gamma voltage according to a plurality of data control signals provided from the timing controller TC. The data driver DD may supply the converted data voltage to a plurality of data lines DL.

The timing controller TC aligns image data input from the outside and supplies the image data to the data driver DD. The timing controller TC may generate a gate control signal and a data control signal by using a synchronization signal input from the outside, for example, a dot clock signal, a data enable signal, and a horizontal/vertical synchronization signal. Here, the horizontal synchronization signal is a signal representing a time taken to display one horizontal line of a screen and the vertical synchronization signal is a signal representing a time taken to display a screen of one frame. The data enable signal may correspond to a signal indicating a period for which a data voltage is supplied to a pixel. Further, the timing controller TC supplies the generated gate control signal and data control signal to the gate driver GD and the data driver DD, respectively, to control the gate driver GD and the data driver DD.

The display panel PN is configured to display images to a user and includes a plurality of sub pixels SP. In the display panel PN, the plurality of scan lines SL and the plurality of data lines DL intersect each other, and each of the plurality of sub pixels SP is connected to the scan line SL and the data line DL. In addition, although not illustrated in the drawings, each of the plurality of sub pixels SP may be connected to a high potential power line, a low potential power line, a reference line, and the like.

In the display panel PN, a display area AA and a non-display area NA surrounding the display area AA may be defined.

The display area AA is an area in which images are displayed in the display device 100. In the display area AA, a plurality of sub pixels SP constituting a plurality of pixels PX and a circuit for driving the plurality of sub pixels SP may be disposed. The plurality of sub pixels SP is a minimum unit constituting the display area AA, and k sub pixels SP may form one pixel PX (k is a natural number). In each of the plurality of sub pixels SP, a light emitting element, a thin film transistor for driving the light emitting element, and the like may be disposed.

An active layer of thin transistor may be formed of a semiconductor material, such as an oxide semiconductor, amorphous semiconductor, or polycrystalline semiconductor, but is not limited thereto.

The oxide semiconductor material may have an effect of preventing or reducing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility and has low energy power consumption and high reliability. The polycrystalline semiconductor may be made of polycrystalline silicon (poly-Si), but is not limited thereto.

The amorphous semiconductor material may be made of amorphous silicon (a-Si), but is not limited thereto.

The plurality of light emitting elements may be differently defined depending on the type of the display panel PN. For example, when the display panel PN is an inorganic light emitting display panel, the light emitting element may be a light emitting element (LED) or a micro light emitting element (micro-LED).

In the display area AA, a plurality of signal lines for transmitting various signals to the plurality of sub pixels SP is disposed. For example, the plurality of signal lines may include a plurality of data lines DL which supplies a data voltage to each of the plurality of sub pixels SP, a plurality of scan lines SL which supplies a gate voltage to each of the plurality of sub pixels SP, and the like. The plurality of scan lines SL may extend in one direction in the display area AA and be connected to the plurality of sub pixels SP, and the plurality of data lines DL may extend in a direction different from the one direction in the display area AA and be connected to the plurality of sub pixels SP. In addition, in the display area AA, a low potential power line, a high potential power line, and the like may be further disposed, but are not limited thereto.

The non-display area NA is an area where an image is not displayed and may be defined as an area extending from the display area AA.

The non-display area NA may be an area adjacent to the display area AA. Further, the non-display area NA may be an area disposed adjacent to the display area AA and configured to surround the display area AA. The non-display area NA may be disposed in an edge region surrounding the display area AA which displays an image. However, the present disclosure is not limited thereto.

For example, the non-display area NA may include a first non-display area located outside the display area AA in a first direction, a second non-display area located outside the display area AA in a second direction intersecting the first direction, a third non-display area located outside the display area AA in the opposite direction to the first direction, and a fourth non-display area located outside the display area AA in the direction opposite to the second direction.

For another example, a boundary area between the display area AA and the non-display area NA may be bent so that the non-display area NA may be located below the display area. In this case, when the user looks at the display apparatus from the front, there may be little or no non-display area NA visible to the user.

In the non-display area NA, a link line and a pad electrode for transmitting a signal to the sub pixel SP of the display area AA, or a driving IC, such as a gate driver IC or a data driver IC, may be disposed. The non-display area NA may be located on a rear surface of the display panel PN, that is, a surface on which the sub pixels SP are not disposed or may be omitted, and is not limited as illustrated in the drawing.

Meanwhile, a driver such as a gate driver GD, a data driver DD, and a timing controller TC may be connected to the display panel PN in various ways. For example, the gate driver GD may be mounted in the non-display area NA in a gate-in-panel (GIP) manner or mounted between the plurality of sub pixels SP in the display area AA in a gate-in-display area (GIA) manner. For example, the data driver DD and the timing controller TC are formed in separate flexible film and printed circuit board and may be electrically connected to the display panel PN by bonding the flexible film and the printed circuit board to the pad electrode formed in the non-display area NA of the display panel PN. If the gate driver GD is mounted in the GIP manner and the data driver DD and the timing controller TC transmit signals to the display panel PN through the pad electrode of the non-display area NA, it is necessary to secure the area of the non-display area NA for disposing the gate driver GD and the pad electrode, and the bezel may increase.

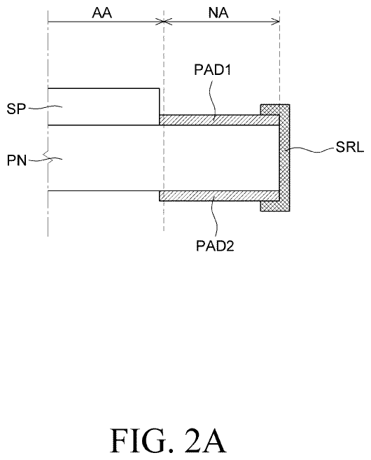

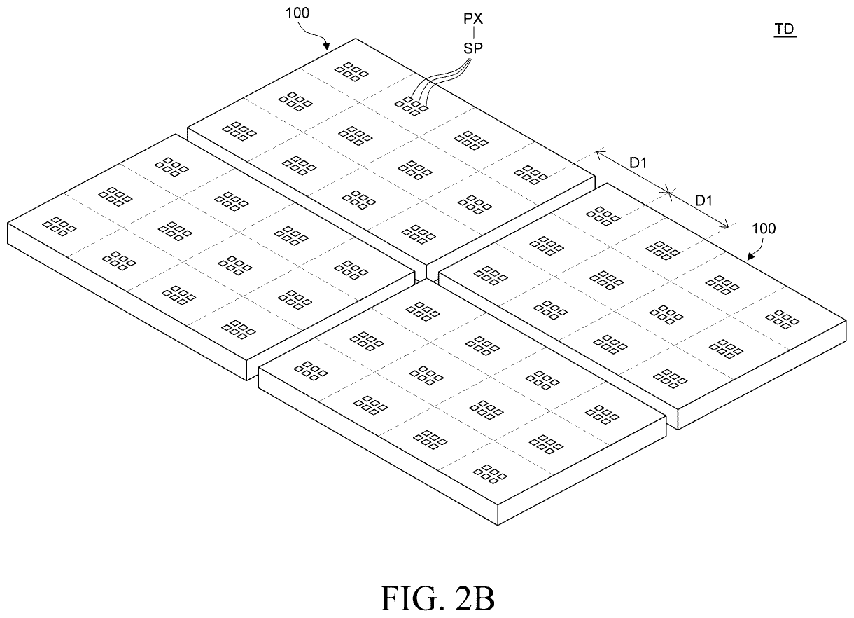

In contrast, when the gate driver GD is mounted in the display area AA in the GIA manner and a side line SRL which connects the signal line on the front surface of the display panel PN to the pad electrode on the rear surface of the display panel PN is formed to bond the flexible film and the printed circuit board to the rear surface of the display panel PN, the non-display area NA on the front surface of the display panel PN may be minimized or reduced. That is, when the gate driver GD, the data driver DD, and the timing controller TC are connected to the display panel PN as described above, a zero bezel in which there is substantially no bezel may be implemented, and a more detailed description will be described with reference to FIGS. 2A and 2B.

FIG. 2A is a partial cross-sectional view of a display device according to an example embodiment of the present disclosure. FIG. 2B is a perspective view of a tiling display device according to an example embodiment of the present disclosure.

In the non-display area NA of the display panel PN, a plurality of pad electrodes for transmitting various signals to the plurality of sub pixels SP is disposed. For example, a first pad electrode PAD1 for transmitting a signal to the plurality of sub pixels SP is disposed in the non-display area NA on the front surface of the display panel PN, and a second pad electrode PAD2 electrically connected to a driving component such as a flexible film and a printed circuit board is disposed in the non-display area NA on the rear surface of the display panel PN.

In this case, although not illustrated in the drawings, various signal lines connected to the plurality of sub pixels SP, for example, a scan line SL or a data line DL extend from the display area AA to the non-display area NA to be electrically connected to the first pad electrode PAD1.

Further, the side line SRL is disposed along the side surface of the display panel PN. The side line SRL may electrically connect the first pad electrode PAD1 on the front surface of the display panel PN and the second pad electrode PAD2 on the rear surface of the display panel PN. Therefore, a signal from the driving component on the rear surface of the display panel PN may be transmitted to the plurality of sub pixels SP through the second pad electrode PAD2, the side line SRL, and the first pad electrode PAD1. Accordingly, a signal transmission path is formed from the front surface of the display panel PN to the side surface and the rear surface to minimize or reduce the area of the non-display area NA of the display panel PN.

Further, as shown in FIG. 2B, a tiling display device TD having a large screen may be implemented by connecting a plurality of display devices 100. In this case, when the tiling display device TD is implemented using the display device 100 with a minimized or reduced bezel as illustrated in FIG. 2A, a seam area in which an image between the display device 100 and the display device 100 is not displayed is minimized or reduced, thereby improving the display quality.

For example, the plurality of sub pixels SP may form one pixel PX, and an interval D1 between an outermost pixel PX of one display device 100 and an outermost pixel PX of another display device 100 adjacent to one display device 100 may be implemented to be equal to an interval D1 between pixels PX in one display device 100. Accordingly, the distance between the pixels PX between the display device 100 and the display device 100 is constantly configured to minimize or reduce the seam area.

The plurality of sub pixels SP may be composed of a red (R) sub-pixel, a green (G) sub-pixel, and a blue (B) sub-pixel, or composed of a red (R) sub-pixel, a green (G) sub-pixel, a blue (B) sub-pixel, and a white (W) sub-pixel. However, the present disclosure is not limited thereto. A plurality of subpixels SP constituting unit pixel may be variously modified in colors and configurations, as necessary.

For example, each of the plurality of subpixels SP may emit light having different wavelengths from each other. For example, the plurality of subpixels SP may include red, green, and blue subpixels, in which the red, green, and blue subpixels may be disposed in a repeated manner. Alternatively, the plurality of subpixels SP may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a subpixel that emits light of a color different from that of a blue subpixel may have a different light-emitting area from that of the blue subpixel. For example, the red subpixel, the blue subpixel, and the green subpixel, or the red subpixel, the blue subpixel, the white subpixel, and the green subpixel may each has a different light-emitting area.

However, FIGS. 2A and 2B are illustrative so that the display device 100 according to an example embodiment of the present disclosure may be a general display device with a bezel, but is not limited thereto.

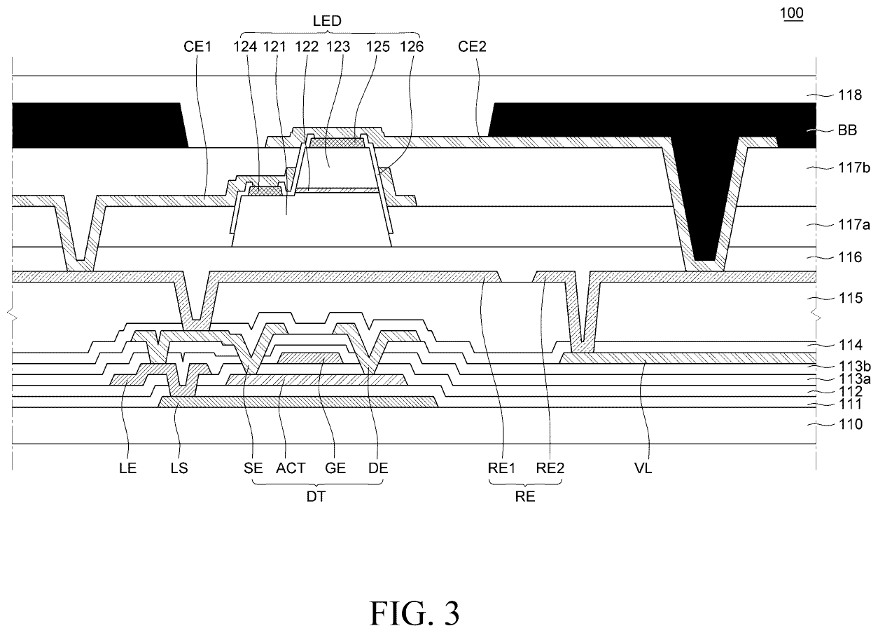

FIG. 3 is a cross-sectional view of a display device according to an example embodiment of the present disclosure. For example, FIG. 3 is a cross-sectional view of one sub pixel SP.

As shown in FIG. 3, in each of the plurality of sub pixels SP of the display panel PN of the display device 100 according to the example embodiment of the present disclosure, a substrate 110, a buffer layer 111, a gate insulating layer 112, a first interlayer insulating layer 113a, a second interlayer insulating layer 113b, a passivation layer 114, an overcoating layer 115, an adhesive layer 116, a first planarization layer 117a, a second planarization layer 117b, a black bank BB, a third planarization layer 118, a driving transistor DT, a power line VL, a light emitting element LED, a plurality of reflective electrodes RE, an auxiliary electrode LE, a plurality of first connection electrodes CE1, and a plurality of second connection electrodes CE2 may be disposed.

First, the substrate 110 is a component for supporting various components included in the display device 100 and may be made of an insulating material. For example, the substrate 110 may be made of glass, resin, or the like. In addition, the substrate 110 may include polymer or plastic, or may be made of a material having flexibility. For example, the substrate 110 may include a flexible polymer film. For example, the flexible polymer film may be made of any one of polyimide (PI), polyethylene terephthalate (PET), acrylonitrile-butadiene-styrene copolymer(ABS), polymethyl methacrylate(PMMA), polyethylene naphthalate (PEN), polycarbonate (PC), polyethersulfone (PES), polyarylate (PAR), polysulfone (PSF), cyclic olefin copolymer(COC), triacetylcellulose(TAC), polyvinyl alcohol(PVA), and polystyrene(PS). For example, the substrate 100 may include a transparent polyimide material, and the present disclosure is not limited thereto.

The light shielding layer LS may be disposed in each of the plurality of sub pixels SP on the substrate 110. The light shielding layer LS blocks light incident onto an active layer ACT of the driving transistor DT to be described below from a lower portion of the substrate 110. Light which is incident onto the active layer ACT of the driving transistor DT is blocked by the light shielding layer LS to minimize or reduce a leakage current.

A buffer layer 111 may be disposed on the substrate 110 and the light shielding layer LS. The buffer layer 111 may reduce penetration of moisture or impurities through the substrate 110. For example, the buffer layer 111 may be configured as a single layer or multilayer made of silicon oxide (SiOx) or silicon nitride (SiNx). For example, the buffer layer 111 may be formed as a single layer of any one of a silicon oxide (SiOx) film, a silicon nitride (SiNx) film, and a silicon oxynitride (SiON) film, or a multilayer thereof. For example, the buffer layer 111 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si). However, the present disclosure is not limited thereto. However, the buffer layer 111 may be omitted depending on the type of substrate 110 or the type of transistor, but is not limited thereto.

The driving transistor DT may be disposed on the buffer layer 111. The driving transistor DT includes an active layer ACT, a gate electrode GE, a source electrode SE, and a drain electrode DE.

The active layer ACT may be disposed on the buffer layer 111. The active layer ACT may be formed of a semiconductor material such as an oxide semiconductor, amorphous silicon, or polysilicon, but is not limited thereto.

The gate insulating layer 112 may be disposed on the active layer ACT. The gate insulating layer 112 is an insulating layer which insulates the active layer ACT from the gate electrode GE and may be configured by a single layer or a double layer of silicon oxide (SiOx) or silicon nitride (SiNx), for example, the gate insulation layer 112 may be formed as a single layer of any one of a silicon oxide (SiOx) film, a silicon nitride (SiNx) film, and a silicon oxynitride (SiON) film, or a multilayer thereof. For example, the gate insulation layer 112 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but is not limited thereto.

The gate electrode GE may be disposed on the gate insulating layer 112. The gate electrode GE may be configured by a conductive material such as copper (Cu), aluminum (Al), molybdenum (Mo), nickel (Ni), titanium (Ti), chromium (Cr), or an alloy thereof, but is not limited thereto.

A first interlayer insulating layer 113a and a second interlayer insulating layer 113b may be disposed on the gate electrode GE. In the first interlayer insulating layer 113a and the second interlayer insulating layer 113b, a contact hole through which the source electrode SE and the drain electrode DE are connected to the active layer ACT is formed. The first interlayer insulating layer 113a and the second interlayer insulating layer 113b are insulating layers for protecting components disposed below the first interlayer insulating layer 113a and the second interlayer insulating layer 113b and may be configured by a single layer or a double layer of silicon oxide (SiOx) or silicon nitride (SiNx), for example, each of the first interlayer insulating layer 113a and the second interlayer insulating layer 113b may be formed as a single layer of any one of a silicon oxide (SiOx) film, a silicon nitride (SiNx) film, and a silicon oxynitride (SiON) film, or a multilayer thereof. For example, each of the first interlayer insulating layer 113a and the second interlayer insulating layer 113b may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but are not limited thereto.

The source electrode SE and the drain electrode DE which are electrically connected to the active layer ACT may be disposed on the second interlayer insulating layer 113b. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

Meanwhile, in the present disclosure, it has been described that the first interlayer insulating layer 113a and the second interlayer insulating layer 113b, that is, a plurality of insulating layers is disposed between the gate electrode GE, the source electrode SE, and the drain electrode DE. However, only one insulating layer may be disposed between the gate electrode GE, the source electrode SE, and the drain electrode DE, but is not limited thereto.

Further, as illustrated in the drawing, when a plurality of insulation layers, such as the first interlayer insulation layer 113a and the second interlayer insulation layer 113b, are disposed between the gate electrode GE, the source electrode SE, and the drain electrode DE, an electrode may be additionally formed between the first interlayer insulation layer 113a and the second interlayer insulation layer 113b, and the additionally formed electrode may form a capacitor with another configuration disposed below the first interlayer insulation layer 113a or above the second interlayer insulation layer 113b, but is not limited thereto.

The auxiliary electrode LE may be disposed on the gate insulating layer 112. The auxiliary electrode LE is an electrode which electrically connects the light shielding layer LS below the buffer layer 111 to any one of the source electrode SE and the drain electrode DE on the second interlayer insulating layer 113b. For example, the light shielding layer LS is electrically connected to any one of the source electrode SE or the drain electrode DE through the auxiliary electrode LE so as not to operate as a floating gate. Therefore, fluctuation of a threshold voltage of the driving transistor DT caused by the floated light shielding layer LS may be minimized or reduced. Even though in the drawing, it is illustrated that the light shielding layer LS is connected to the source electrode SE, the light shielding layer LS may also be connected to the drain electrode DE, but is not limited thereto.

The power line VL may be disposed on the second interlayer insulating layer 113b. The power line VL is electrically connected to the light emitting element LED together with the driving transistor DT to allow the light emitting element LED to emit light. The power line VL may be configured by a conductive material such as copper (Cu), aluminum (Al), molybdenum (Mo), nickel (Ni), titanium (Ti), chrome (Cr), or an alloy thereof, but is not limited thereto.

The passivation layer 114 may be disposed on the driving transistor DT and the power line VL. The passivation layer 114 may protect the driving transistor DT and the power line VL from the penetration of moisture or impurities. For example, the passivation layer 114 may be configured as a single layer or multilayer made of silicon oxide (SiOx) or silicon nitride (SiNx). However, the present disclosure is not limited thereto. However, the passivation layer 114 may be omitted depending on the type of substrate 110 or the type of transistor, but is not limited thereto.

The overcoating layer 115 may be disposed on the passivation layer 114. The overcoating layer 115 may planarize an upper portion of the substrate 110 on which the driving transistor DT is disposed. The overcoating layer 115 may be configured by a single layer or a double layer, and for example, may be formed of photoresist or an acrylic organic material, but is not limited thereto.

A plurality of reflective electrodes RE spaced apart from each other may be disposed on the overcoating layer 115. The plurality of reflective electrodes RE electrically connects the light emitting element LED to the power line VL and the driving transistor DT and may serve as a reflective plate that reflects light emitted from the light emitting element LED to an upper portion of the light emitting element LED. The plurality of reflective electrodes RE is formed of a conductive material having excellent reflection characteristics to reflect light emitted from the light emitting element LED toward the upper portion of the light emitting element LED.

The plurality of reflective electrodes RE may include a first reflective electrode RE1 and a second reflective electrode RE2. The first reflective electrode RE1 may electrically connect the driving transistor DT and the light emitting element LED. The first reflective electrode RE1 may be connected to the source electrode SE or the drain electrode DE of the driving transistor DT through a contact hole formed in the passivation layer 114 and the overcoating layer 115. Further, the first reflective electrode RE1 may be electrically connected to the first electrode 124 of the light emitting element LED through the first connection electrode CE1.

The second reflective electrode RE2 may electrically connect the power line VL and the light emitting element LED. The second reflective electrode RE2 may be connected to the power line VL through a contact hole formed in the passivation layer 114 and the overcoating layer 115, and may be electrically connected to the second electrode 125 of the light emitting element LED through a second connection electrode CE2 to be described below.

The adhesive layer 116 is formed on the front surface of the substrate 110 on the plurality of reflective electrodes RE to fix the light emitting element LED disposed on the adhesive layer 116. The adhesive layer 116 may be made of a photocurable adhesive material that may be cured by light. For example, the adhesive layer 116 may be formed of an acrylic material including a photoresist, but is not limited thereto.

The plurality of light emitting elements LED may be disposed in each of the plurality of sub pixels SP on the adhesive layer 116. The plurality of light emitting elements LED is an element which emits light by a current and may include a light emitting element LED which emits red light, green light, and blue light and may implement various colored light including white by a combination thereof. For example, the plurality of light emitting elements LED may be a light emitting element (LED) or a micro LED (micro-LED), but is not limited thereto.

The light emitting element LED may include a first semiconductor layer 121, an emission layer 122, a second semiconductor layer 123, a first electrode 124, a second electrode 125, and a passivation film 126.

The first semiconductor layer 121 may be disposed on the adhesive layer 116, and the second semiconductor layer 123 may be disposed on the first semiconductor layer 121. The first semiconductor layer 121 and the second semiconductor layer 123 may be layers formed by doping n-type or p-type impurities into a specific material. For example, each of the first semiconductor layer 121 and the second semiconductor layer 123 may be layers doped with n-type and p-type impurities into a material such as gallium nitride (GaN), indium aluminum phosphide (InAlP), or gallium arsenide (GaAs). Further, the p-type impurity may be magnesium (Mg), zinc (Zn), beryllium (Be), and the like, and the n-type impurity may be silicon (Si), germanium, tin (Sn), and the like, but not limited thereto.

A portion of the first semiconductor layer 121 may be disposed to protrude outward from the second semiconductor layer 123. The top surface of the first semiconductor layer 121 may include a portion overlapping the bottom surface of the second semiconductor layer 123 and a portion disposed outside the bottom surface of the second semiconductor layer 123. For example, the first semiconductor layer 121 may protrude outward from the second semiconductor layer 123 in some directions. The light emitting element LED may be a lateral light emitting element LED. However, the sizes and shapes of the first semiconductor layer 121 and the second semiconductor layer 123 may be variously modified, but are not limited thereto.

The emission layer 122 may be disposed between the first semiconductor layer 121 and the second semiconductor layer 123. The emission layer 122 may receive holes and electrons from the first semiconductor layer 121 and the second semiconductor layer 123 to emit light.

The emission layer 122 may be formed by a single layer or a multi-quantum well (MQW) structure, and for example, may be formed of indium gallium nitride (InGaN) or gallium nitride (GaN), but is not limited thereto.

The first electrode 124 may be disposed on the first semiconductor layer 121. The first electrode 124 is an electrode for electrically connecting the driving transistor DT and the first semiconductor layer 121. In this case, the first semiconductor layer 121 may be a semiconductor layer doped with an n-type impurity, and the first electrode 124 may be a cathode. The first electrode 124 may be disposed on a top surface of the first semiconductor layer 121 exposed from the emission layer 122 and the second semiconductor layer 123. The first electrode 124 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 125 may be disposed on the second semiconductor layer 123. The second electrode 125 may be disposed on the top surface of the second semiconductor layer 123. In this case, because the second semiconductor layer 123 is disposed on the first semiconductor layer 121, the second electrode 125 disposed on the top surface of the second semiconductor layer 123 may be disposed higher than the first electrode 124 disposed on the top surface of the first semiconductor layer 121. The second electrode 125 is an electrode which electrically connects the power line VL and the second semiconductor layer 123. In this case, the second semiconductor layer 123 may be a semiconductor layer doped with a p-type impurity, and the second electrode 125 may be an anode. The second electrode 125 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the passivation film 126 may be disposed to surround the first semiconductor layer 121, the emission layer 122, the second semiconductor layer 123, the first electrode 124, and the second electrode 125. The passivation film 126 may be formed of an insulating material to protect the first semiconductor layer 121, the emission layer 122, and the second semiconductor layer 123. Further, a contact hole which exposes the first electrode 124 and the second electrode 125 is formed in the passivation film 126, and the first connection electrode CE1 and the second connection electrode CE2 to be formed later and the first electrode 124 and the second electrode 125 may be electrically connected through the contact hole.

Meanwhile, in the display device 100 according to the example embodiment of the present disclosure, the light emitting elements LED disposed in different sub pixels SP are configured with different shapes to distinguish the plurality of light emitting elements LED. Therefore, when the light emitting element LED is self-assembled, the plurality of light emitting elements LED is formed to have different shapes to be self-assembled in a position corresponding to each of the plurality of sub pixels SP.

Meanwhile, the present disclosure is not limited thereto, and the size and shape of the light emitting elements LED may be the same. That is, the light emitting element LED is transferred by a separate transfer substrate rather than a self-assembling method to be disposed at a position corresponding to the plurality of sub pixels SP.

The first planarization layer 117a may be disposed on the adhesive layer 116. The first planarization layer 117a is disposed so as to surround a part of side surfaces of the plurality of light emitting elements LED to fix and protect the plurality of light emitting elements LED.

For example, the first planarization layer 117a may be disposed to surround the passivation film 126 disposed on the lower edge of the light emitting element LED. Therefore, the disconnection of the first connection electrode CE1 due to a torn passivation film 126 may be prevented or suppressed. For example, during the process of separating the wafer and the light emitting element LED, a part of the passivation film 126 may be torn off at the lower edge of the light emitting element LED. Therefore, the passivation film 126 may expose a part of the first semiconductor layer 121 of the lower edge of the light emitting element LED. Accordingly, a step may be generated in the lower edge of the light emitting element LED due to the torn passivation film 126. In this case, when the first connection electrode CE1 is disposed to surround the side surface of the passivation film 126, the first connection electrode CE1 may be disconnected by a step caused by the torn passivation film 126.

Accordingly, before disposing the first connection electrode CE1, the first planarization layer 117a is disposed so as to surround the lower edge of the light emitting element LED to separate the lower edge of the light emitting element LED from the first connection electrode CE1. Therefore, even though an undercut structure due to the torn passivation film 126 is formed on the lower edge of the light emitting element LED, the first planarization layer 117a is in contact with at least a part of the side surface of the light emitting element LED to fill the undercut structure, thereby minimizing or reducing the short of the first connection electrode CE1 due to the undercut structure.

The first planarization layer 117a may be configured by a single layer or a double layer, and for example, may be formed of photoresist or an acrylic organic material, but is not limited thereto.

Meanwhile, the first planarization layer 117a may be lower than the height of the first electrode 124. For example, the thickness of the first planarization layer 117a may be adjusted by performing an ashing process. For example, after applying the material layer of the first planarization layer 117a to cover the light emitting element LED, an ashing process of reducing the overall thickness of the material layer of the first planarization layer 117a is performed to form the height of the first planarization layer 117a to be lower than the height of the first electrode 124. Accordingly, the first planarization layer 117a may expose the first electrode 124. Accordingly, the first connection electrode CE1 disposed on the first planarization layer 117a may be easily connected to the first electrode 124 without a separate contact hole.

The first connection electrode CE1 may be disposed on the first planarization layer 117a. The first connection electrode CE1 is an electrode which is disposed in each of the plurality of sub pixels SP to electrically connect the light emitting element LED and the driving transistor DT. The first connection electrode CE1 may be connected to the first reflective electrode RE1 through a contact hole formed in the first planarization layer 117a and the adhesive layer 116. Accordingly, the first connection electrode CE1 may be electrically connected to any one of the source electrode SE and the drain electrode DE of the driving transistor DT through the first reflective electrode RE1. For example, the first connection electrode CE1 may connect the first electrode 124 of the light emitting element LED to the source electrode SE of the driving transistor DT, but is not limited thereto.

Meanwhile, the first connection electrode CE1 may be formed by disposing the material layer of the first connection electrode CE1 so as to cover the light emitting element LED and then partially removing a part of the side surface and the top surface of the second semiconductor layer 123 and the material layer of the first connection electrode CE1 disposed on the second electrode 125. For example, after applying the photoresist on the light emitting element LED, the photoresist disposed on the top surface of the second electrode 125 and a part of the top surface and the side surface of the second semiconductor layer 123 is removed by an ashing process to expose the second electrode 125. Therefore, only the top surface of the second electrode 125, a part of the side surface of the second semiconductor layer 123, and a part disposed on the top surface of the material layer of the first connection electrode CE1 may be exposed. Further, the material layer of the first connection electrode CE1 exposed by the ashing process is removed to form the first connection electrode CE1, but it is not limited thereto.

The second planarization layer 117b may be disposed on the first planarization layer 117a and the plurality of first connection electrodes CE1. The second planarization layer 117b planarizes an upper portion of the substrate 110 on which the light emitting element LED is disposed together with the first planarization layer 117a and may fix the light emitting element LED onto the substrate 110 together with the adhesive layer 116.

Further, the second planarization layer 117b may be disposed to cover the first connection electrode CE1 so that the first connection electrode CE1 and the second connection electrode CE2 are separated from each other. Accordingly, a short circuit between the first connection electrode CE1 and the second connection electrode CE2 may be prevented or suppressed.

For example, only the second planarization layer 117b may be disposed between the first connection electrode CE1 and the second connection electrode CE2. The second planarization layer 117b may be configured as a single layer or multilayer and made of a photoresist or an acrylic-based organic material, for example. However, the present disclosure is not limited thereto.

The second connection electrode CE2 may be disposed on the second planarization layer 117b. The second connection electrode CE2 is an electrode for electrically connecting the light emitting element LED and the power line VL. The second connection electrode CE2 may be connected to the second reflective electrode RE2 through contact holes formed in the second planarization layer 117b, the first planarization layer 117a, and the adhesive layer 116. Accordingly, the second connection electrode CE2 may be electrically connected to the power line VL through the second reflective electrode RE2. For example, the second connection electrode CE2 may connect the second electrode 125 of the light emitting element LED and the power line VL, but is not limited thereto.

A black bank BB may be disposed on the second planarization layer 117b and the second connection electrode CE2. The black bank BB may be disposed not to overlap the light emitting element LED to define an emission area. For example, the black bank BB may cover an edge of the second connection electrode CE2 connected to each light emitting element LED to define an emission area. That is, the black bank BB may divide the plurality of sub pixels SP. The black bank BB may be formed of an insulating material to insulate the second connection electrodes CE2 of the adjacent sub pixels SP from each other. Further, the black bank BB may include a black component having a high light absorption rate to suppress color mixture between adjacent sub pixels SP. The black bank BB may be formed of, for example, polyimide resin, acrylic resin, or benzocyclobutene (BCB) resin, but is not limited thereto.

For example, the black bank BB may be patterned in a photolithography process by including an organic insulating material having photosensitivity. Further, a spacer with a preset height may be formed on the black bank BB. Here, the black bank BB and the spacer may be integrated with the same organic insulating material. Additionally, the spacer may secure a gap between the fine metal mask (FMM) and the anode electrode to prevent or suppress the FMM from coming into contact with the anode electrode in a deposition process of the light-emitting element made of an organic compound.

The third planarization layer 118 may be disposed on the second planarization layer 117b and the black bank BB. The third planarization layer 118 is disposed to cover the top surface of the light emitting element LED to planarize the upper portion of the substrate 110 on which the light emitting element LED is disposed and fix and protect the light emitting element LED. Therefore, the third planarization layer 118 may be referred to as a protective layer or a capping layer, but is not limited thereto. The third planarization layer 118 may be configured by a single layer or a double layer, and for example, may be formed of a photoresist or an acrylic organic material, but is not limited thereto.

Meanwhile, an encapsulation layer may be disposed on the third planarization layer 118 and may prevent or suppress the light emitting device from being damaged by an external impact and water. The encapsulation layer may include an inorganic insulating material layer and an inorganic insulating material layer, which are alternately stacked. For example, the organic insulating material layer may be disposed between adjacent inorganic insulating material layers.

For example, the encapsulation layer may include a first inorganic encapsulation layer, a first organic encapsulation layer, and a second inorganic encapsulation layer stacked sequentially.

Alternatively, the encapsulation layer may include a first inorganic encapsulation layer, a first organic encapsulation layer, a second inorganic encapsulation layer, a second organic encapsulation layer, and a third inorganic encapsulation layer stacked sequentially. However, the present disclosure is not limited thereto.

The first inorganic encapsulation layer, the second inorganic encapsulation layer, and the third inorganic encapsulation layer may serve to block the penetration of moisture or oxygen. The first inorganic encapsulation layer, the second inorganic encapsulation layer, and the third inorganic encapsulation layer may be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer may each have a larger thickness than each of the first inorganic encapsulation layer, the second inorganic encapsulation layer, and the third inorganic encapsulation layer in order to adsorb or block particles that may be produced during a process of manufacturing the display device. The first organic encapsulation layer and the second organic encapsulation layer may fill cracks that may be formed in the first inorganic encapsulation layer and the second inorganic encapsulation layer. The first organic encapsulation layer and the second organic encapsulation layer may planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer may planarize an upper portion of the first inorganic encapsulation layer by covering particles on the first inorganic encapsulation layer. For example, the second organic encapsulation layer may planarize an upper portion of the second inorganic encapsulation layer by covering particles on the second inorganic encapsulation layer. The first organic encapsulation layer and the second organic encapsulation layer may be made of an organic material, and for example, epoxy polymer, acrylic polymer, or the like may be used. However, the present disclosure is not limited thereto.

Meanwhile, the encapsulation layer is not limited to three or five layers, for example, n layers alternately stacked between inorganic encapsulation layer and organic encapsulation layer (where n is an integer greater than 3) may be included.

During a process of placing or transferring a plurality of light emitting elements on a substrate, some light emitting elements may be erroneously aligned or erroneously disposed. At this time, when a subsequent process is performed in a state in which some light emitting elements are erroneously aligned or erroneously disposed, a short defect between electrodes may occur.

For example, when the light emitting element is erroneously aligned to connect the same electrode to the first electrode and the second electrode of the light emitting element, or electrodes respectively connected to the first electrode and the second electrode of the light emitting element are not separately disposed and overlap to cause a short defect, the light emitting element may not emit light normally.

In the display device 100 according to the example embodiment of the present disclosure, the first connection electrode CE1 and the first electrode 124 of the light emitting element LED are self-aligned to be connected. For example, a material layer of the first planarization layer 117a may be disposed to surround the light emitting element LED. Next, the material layer of the first planarization layer 117a may be ashed to expose the first electrode 124. Subsequently, a material layer of the first connection electrode CE1 may be disposed on the first planarization layer 117a. At this time, the photoresist is applied on the material layer of the first connection electrode CE1 and the photoresist may be removed by the ashing process until the second electrode 125 of the light emitting element LED is exposed. Subsequently, the material layer of the first connection electrode CE1 exposed by the ashing process is removed so that only the material layer of the first connection electrode CE1 disposed on the first electrode 124 and the first planarization layer 117a remains to form the first connection electrode CE1. Accordingly, the first connection electrode CE1 and the first electrode 124 may be self-aligned by the ashing process of the first planarization layer 117a and the photoresist without precisely aligning the positions of the first electrode 124 and the first connection electrode CE1. Therefore, it is possible to minimize or reduce the short defect due to the process error.

Further, in the display device 100 according to the example embodiment of the present disclosure, the second connection electrode CE2 and the second semiconductor layer 123 of the light emitting element LED are self-aligned to be connected. For example, the ashing process is performed on the second planarization layer 117b which covers the second semiconductor layer 123 and the second electrode 125 of the light emitting element LED to expose only the second semiconductor layer 123 and the second electrode 125 of the light emitting element LED. In this case, even though the second connection electrode CE2 is formed by forming and patterning the material layer of the second connection electrode CE2 on the front surface of the substrate 110 including the second planarization layer 117b, the second connection electrode CE2 may be in contact with only the top surface of the second electrode 125 exposed from the second planarization layer 117b, and may be spaced apart from the first connection electrode CE1, the emission layer 122, and the first semiconductor layer 121 disposed below the second planarization layer 117b. Therefore, since the second connection electrode CE2 may be in contact with only the top surface of the second electrode 125, there is no need to ensure a process margin in consideration of positions of the first semiconductor layer 121 and the first connection electrode CE1 when the second connection electrode CE2 is formed. Accordingly, the second connection electrode CE2 and the first electrode 124 may be self-aligned by the ashing process of the second planarization layer 117b without precisely aligning the positions of the second electrode 125 and the second connection electrode CE2. Accordingly, the short defect of the first connection electrode CE1 and the second connection electrode CE2 due to the process error may be minimized or reduced.

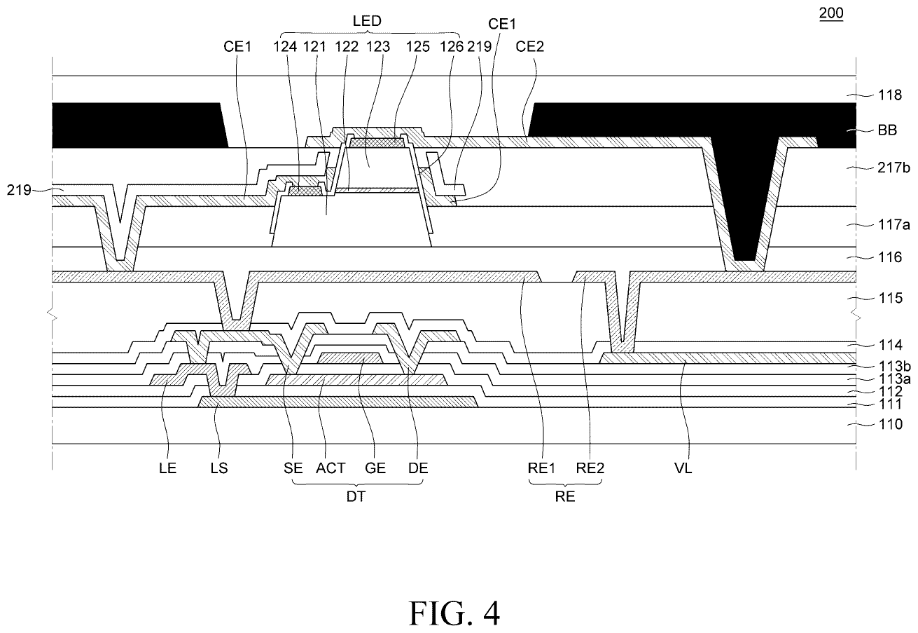

FIG. 4 is a cross-sectional view of a display device according to another example embodiment of the present disclosure. The differences between a display device 200 of FIG. 4 and the display device 100 of FIGS. 1 to 3 are an additional passivation layer 219, a second planarization layer 217b, and a second connection electrode CE2, and other components are substantially the same, so that a redundant description may be omitted.

As shown in FIG. 4, an additional passivation layer 219 may be disposed on a plurality of first connection electrodes CE1. The additional passivation layer 219 may be disposed on the plurality of first connection electrodes CE1 to block the penetration of moisture or impurities into the plurality of reflective electrodes RE1 connected to the plurality of first connection electrodes CE1. For example, the additional passivation layer 219 may be configured as a single layer or multilayer made of an inorganic material such as silicon oxide (SiOx) or silicon nitride (SiNx). However, the present disclosure is not limited thereto.

Further, the additional passivation layer 219 may be disposed to cover at least a part of the first connection electrode CE1 so that the first connection electrode CE1 and the second connection electrode CE2 are separated from each other. Accordingly, the additional passivation layer 219 may prevent or suppress a short circuit between the first connection electrode CE1 and the second connection electrode CE2.

Meanwhile, the additional passivation layer 219 may be disposed to surround a part of the side surface of the light emitting element LED. At this time, the additional passivation layer 219 is disposed on the first connection electrode CE1 so that the additional passivation layer 219 may be disposed to be spaced apart from the light emitting element LED with the first connection electrode CE1 interposed therebetween.

In this case, a height of an uppermost end of the additional passivation layer 219 may be higher than a height of an uppermost end of the first connection electrode CE1. Accordingly, a predetermined space may be formed between the additional passivation layer 219 and the passivation film 126 of the light emitting element LED. Accordingly, the end of the first connection electrode CE1 disposed in the space between the additional passivation layer 219 and the light emitting element LED may be exposed. That is, the additional passivation layer 219 may expose a part of the top surface of the end of the first connection electrode CE1 disposed on the side surface of the light emitting element LED.

A second planarization layer 217b may be disposed on the additional passivation layer 219. The second planarization layer 217b may be disposed to cover the end of the first connection electrode CE1 exposed by the additional passivation layer 219, such that the first connection electrode CE1 and the second connection electrode CE2 may be separated from each other.

Specifically, the second planarization layer 217b may be disposed to fill a space described above, between the additional passivation layer 219 and the light emitting element LED. Accordingly, the second planarization layer 217b may cover the end of the first connection electrode CE1 disposed in the space between the additional passivation layer 219 and the light emitting element LED.

Meanwhile, because the second planarization layer 217b is disposed on the additional passivation layer 219, the second planarization layer 217b may be disposed to cover not only the first connection electrode CE1 exposed by the additional passivation layer 219, but also the additional passivation layer 219. In other words, the second planarization layer 217b may be disposed to cover the passivation film 126 disposed on the side surface of the light emitting element LED, the end of the first connection electrode CE1 disposed to surround a part of the light emitting element LED, and the end of the additional passivation layer 219 adjacent thereto. Therefore, the height of the top surface of the second planarization layer 217b may be higher than the height of the top ends of the first connection electrode CE1 and the additional passivation layer 219, respectively, but is not limited thereto.

The second connection electrode CE2 may be disposed on the second planarization layer 217b. Since the second planarization layer 217b is disposed to cover the additional passivation layer 219, the second connection electrode CE2 disposed on the second planarization layer 217b may be disposed to be spaced apart from the additional passivation layer 219, but is not limited thereto.

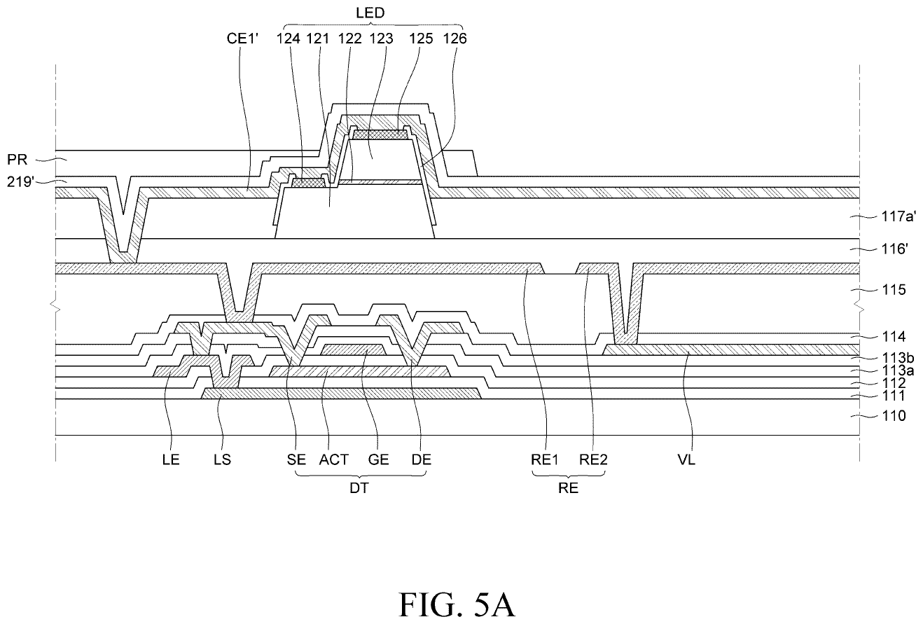

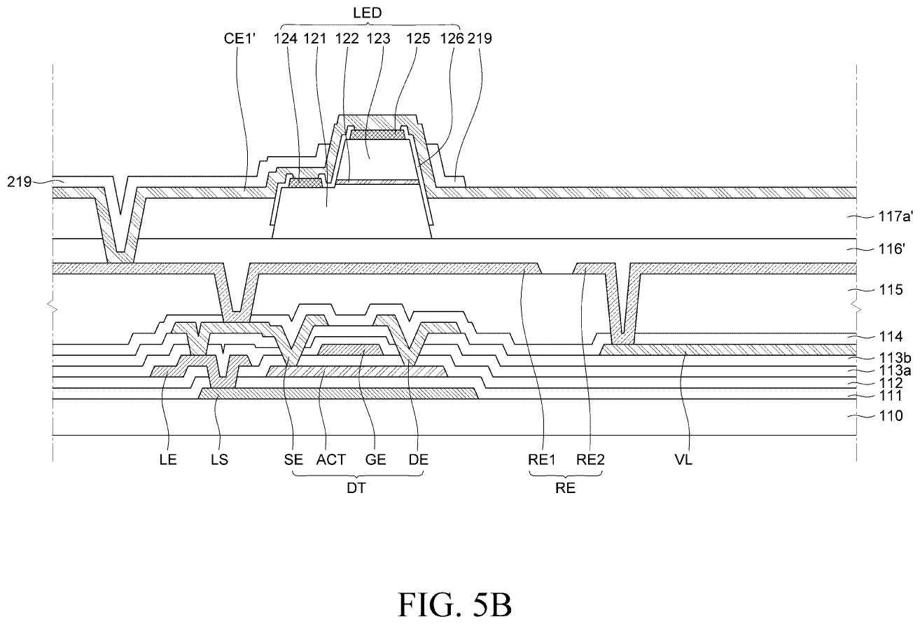

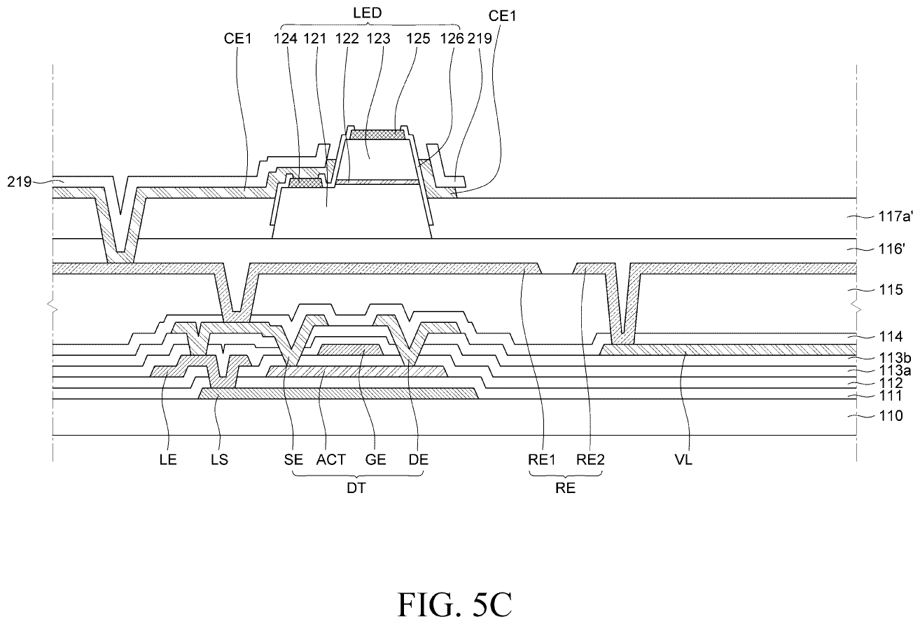

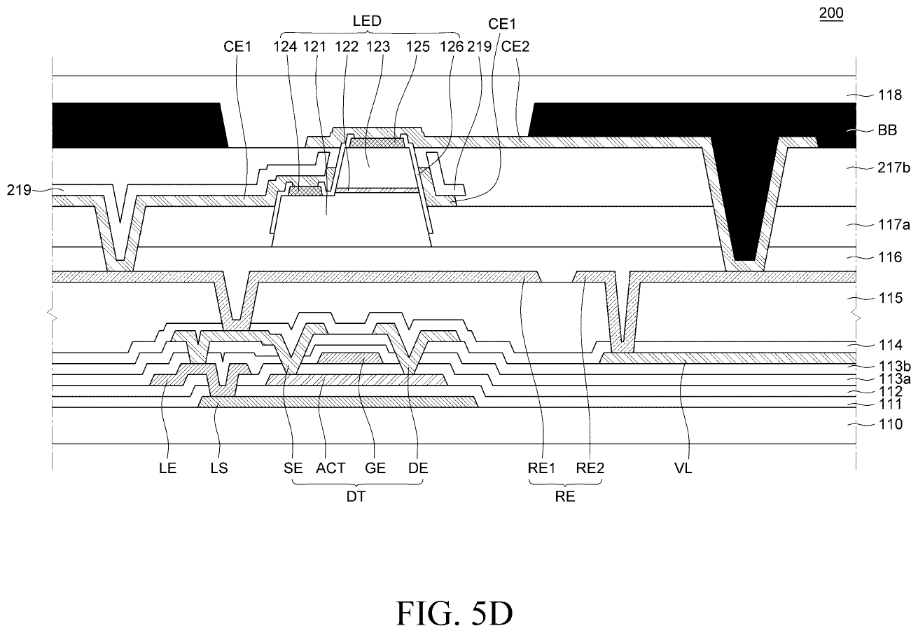

Hereinafter, a method of manufacturing a display device according to another example embodiment of the present disclosure will be described in detail with reference to FIGS. 5A to 5D.

FIGS. 5A to 5D are cross-sectional views for illustrating a process for a method of manufacturing a display device according to another example embodiment of the present disclosure.

First, as shown in FIG. 5A, the light emitting element LED is disposed on the adhesive material layer 116′ and the first planarization material layer 117a′ may be disposed on the adhesive material layer 116′ so as to surround the light emitting element LED.

In this case, a process of etching a part of the adhesive material layer 116′ and the first planarization material layer 117a′ to form the contact hole may be performed. The contact hole formed at this time is a contact hole through which the first reflective electrode RE1 is exposed.

A first connection electrode material layer CE1′ and an additional passivation material layer 219′ may be sequentially disposed on the entire surface of the substrate 110 on the first planarization material layer 117a′ and the light emitting element LED.

Specifically, the first connection electrode material layer CE1′ may be disposed on the entire surface of the substrate 110 so as to cover the light emitting element LED and the first planarization material layer 117a′. Therefore, the first connection electrode material layer CE1′ may also be disposed in the contact hole formed in the first planarization material layer 117a′ and the adhesive material layer 116′. Further, the first connection electrode material layer CE1′ may be disposed to cover all the side surface and the top surface portion of the light emitting element LED.

An additional passivation material layer 219′ may be disposed on the entire surface of the substrate 110 on the first connection electrode material layer CE1′. The additional passivation material layer 219′ may be disposed to be spaced apart from the light emitting element LED, the first planarization material layer 117a′, and the adhesive material layer 116′ by the first connection electrode material layer CE1′.

Meanwhile, a photoresist PR may be disposed on the additional passivation material layer 219′ to surround the light emitting element LED. A height of the photoresist PR may be lower than a height of the second electrode 125 of the light emitting element LED. For example, the thickness of the photoresist PR may be adjusted by performing an ashing process. For example, after applying the photoresist PR to cover the light emitting element LED, an ashing process of reducing the overall thickness of the photoresist PR is performed to form the height of the photoresist PR to be lower than the height of the second electrode 125. Accordingly, in a subsequent process, the second connection electrode CE2 may be easily connected to the second electrode 125.

Next, as shown in FIG. 5B, the additional passivation layer 219 may be formed by etching the additional passivation material layer 219′. Specifically, the additional passivation material layer 219′ exposed from the photoresist PR may be etched to form the additional passivation layer 219.

For example, as the photoresist PR is formed to have a thickness smaller than the thickness of the light emitting element LED, the additional passivation material layer 219′ covering the upper portion of the light emitting element LED may be exposed from the photoresist PR.

The additional passivation layer 219 may be formed by a dry etching process. Therefore, unlike the wet etching, a portion of the additional passivation material layer 219′ that overlaps the photoresist PR may not be removed, but only a portion exposed by the photoresist PR may be removed.

After the additional passivation layer 219 is formed, the photoresist PR may be removed.

Next, as shown in FIG. 5C, the first connection electrode CE1 may be formed by partially removing the first connection electrode material layer CE1′. The additional passivation layer 219 may be formed by etching the first connection electrode material layer CE1′ exposed from the additional passivation layer 219. That is, during the etching process of the first connection electrode material layer CE1′, the additional passivation layer 219 may function as a mask.

Meanwhile, the first connection electrode CE1 may be formed by a wet etching process. Therefore, a portion of the first connection electrode material layer CE1′, which is exposed by the additional passivation layer 219, as well as a portion overlapping the additional passivation layer 219 may be partially removed. Accordingly, the end of the first connection electrode CE1 may be disposed inside or below the end of the additional passivation layer 219. Therefore, the height of the uppermost end of the end of the first connection electrode CE1 disposed on the side surface of the light emitting element LED may be lower than the height of the uppermost end of the adjacent additional passivation layer 219. That is, the first connection electrode material layer CE1′ disposed between the additional passivation layer 219 and the light emitting element LED is partially removed so that a space may be formed between the additional passivation layer 219 and the light emitting element LED. In this way, by forming a space between the additional passivation layer 219 and the light emitting element LED, the second planarization layer 217b may fill the space in a subsequent process to cover the end of the first connection electrode CE1 disposed between the additional passivation layer 219 and the light emitting element LED. Therefore, the first connection electrode CE1 and the second connection electrode CE2 disposed on the second planarization layer 217b may be separated and disposed to be spaced apart from each other.

Next, as shown in FIG. 5D, the second planarization layer 217b, the second connection electrode CE2, the black bank BB, and the third planarization layer 118 are disposed on the additional passivation layer 219 to complete the manufacturing process of the display device 100.

Specifically, although not illustrated in the drawings, the second planarization material layer may be disposed on the entire surface of the substrate 110 on the light emitting element LED, the additional passivation layer 219, and the first planarization material layer 117a′. Subsequently, the thickness of the second planarization material layer may be adjusted by performing an ashing process. For example, after applying the second planarization material layer to cover the light emitting element LED, an ashing process of reducing the overall thickness of the second planarization material layer is performed to form the second planarization layer 217b and the height of the second planarization layer 217b thus formed may be lower than the height of the second electrode 125. Accordingly, the second connection electrode CE2 disposed on the second planarization layer 217b may be easily connected to the second electrode 125.

Subsequently, a process of etching a part of the adhesive material layer 116′, the first planarization material layer 117a′, and the second planarization material layer may be performed to form the contact hole. The contact hole formed at this time is a contact hole through which the second reflective electrode RE2 is exposed.

As described above, the second planarization layer 217b may be formed through an ashing process and a contact hole forming process of the second planarization material layer. As described above, the second planarization layer 217b may be disposed to fill a space between the additional passivation layer 219 and the light emitting element LED. Accordingly, the end of the first connection electrode CE1 exposed by the additional passivation layer 219 may be covered. Accordingly, the first connection electrode CE1 and the second connection electrode CE2 disposed on the second planarization layer 217b may be separated. Accordingly, a short circuit between the first connection electrode CE1 and the second connection electrode CE2 may be prevented or suppressed.

Next, the second connection electrode CE2, the black bank BB, and the third planarization layer 118 are disposed on the second planarization layer 217b to complete the manufacturing process of the display device 100.

For example, the planarization layer may be ashed to expose the second electrode of the light emitting element so that the second electrode and the second connection electrode of the light emitting element are self-aligned. At this time, when the planarization layer is over-ashed, the first connection electrode connected to the first electrode of the light emitting element disposed below the planarization layer may be exposed. In this way, when the second connection electrode is disposed on the planarization layer while the first connection electrode under the planarization layer is exposed, a short defect in which the first connection electrode and the second connection electrode are not separated and are connected to each other may occur.

Accordingly, in the display device 200 according to another example embodiment of the present disclosure, the additional passivation layer 219 disposed on the first connection electrode CE1 so as to cover at least a part of the first connection electrode CE1 may be disposed. Therefore, the additional passivation layer 219 may allow the first connection electrode CE1 and the second connection electrode CE2 to be separated from each other together with the second planarization layer 217b. Accordingly, the additional passivation layer 219 may prevent or suppress a short circuit between the first connection electrode CE1 and the second connection electrode CE2.

In addition, since the additional passivation layer 219 is formed of an inorganic insulating material, moisture or impurities penetrating into the plurality of first connection electrodes CE1 and the plurality of reflective electrodes RE connected thereto may be blocked. Accordingly, lifting of the plurality of reflective electrodes RE by moisture penetration and corrosion may be

### Prevented or Suppressed.

Specifically, in the display device 200 according to another example embodiment of the present disclosure, the second planarization layer 217b covers the first connection electrode CE1 exposed by the additional passivation layer 219 to separate the first connection electrode CE1 and the second connection electrode CE2. For example, a portion of the first connection electrode CE1 exposed by the additional passivation layer 219 by the wet etching process as well as a portion overlapping the additional passivation layer 219 may be partially removed. Therefore, the height of the uppermost end of the end of the first connection electrode CE1 may be formed to be lower than the height of the uppermost end of the additional passivation layer 219. That is, the first connection electrode CE1 disposed between the additional passivation layer 219 and the light emitting element LED is partially removed so that a space may be formed between the additional passivation layer 219 and the light emitting element LED. Accordingly, the second planarization layer 217b disposed on the additional passivation layer 219 may fill a space between the additional passivation layer 219 and the light emitting element LED to cover the end of the first connection electrode CE1 disposed between the additional passivation layer 219 and the light emitting element LED. Accordingly, the first connection electrode CE1 and the second connection electrode CE2 disposed on the second planarization layer 217b may be separated. Therefore, the short defect of the first connection electrode CE1 and the second connection electrode CE2 may be minimized or reduced.

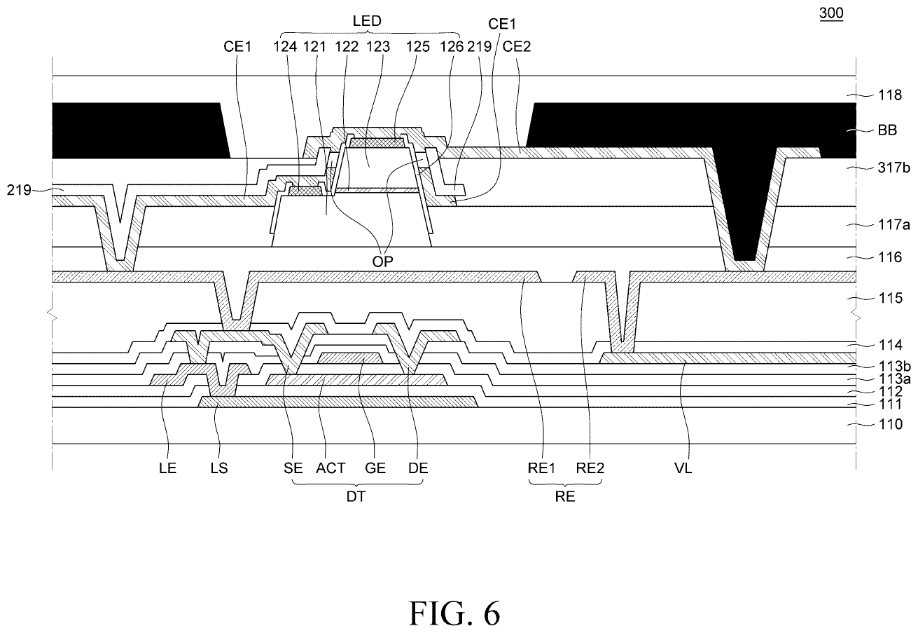

FIG. 6 is a cross-sectional view of a display device according to still another example embodiment of the present disclosure. The differences between a display device 300 of FIG. 6 and the display device 200 of FIG. 5 are an organic pattern OP, a second planarization layer 317b, and a second connection electrode CE2, and other components are substantially the same, so that a redundant description will be omitted.

As shown in FIG. 6, a second planarization layer 317b may be disposed on the additional passivation layer 219. In this case, a height of an uppermost end of the second planarization layer 317b may be lower than a height of an uppermost end of the additional passivation layer 219. Accordingly, the second planarization layer 317b may expose an end of the additional passivation layer 219 disposed on the side surface of the light emitting element LED. That is, the second planarization layer 317b exposes the end of the additional passivation layer 219 so that the end of the first connection electrode CE1 exposed by the additional passivation layer 219 may be exposed.

In other words, the second planarization layer 317b may be disposed to expose an end of the first connection electrode CE1 disposed to surround a part of the side surface of the light emitting element LED and an end of the additional passivation layer 219 adjacent thereto, but is not limited thereto.

Meanwhile, the organic pattern OP may be disposed to cover the end of the first connection electrode CE1 exposed by the additional passivation layer 219, such that the first connection electrode CE1 and the second connection electrode CE2 may be separated from each other.

Specifically, the organic pattern OP may be disposed to fill a space between the additional passivation layer 219 and the light emitting element LED. For example, the first connection electrode CE1 is disposed on the first planarization layer 117a and the side surfaces of the light emitting element LED, the additional passivation layer 219 is disposed on the first connection electrode CE1 and exposes ends of the first connection electrode CE1, the second planarization layer 317b is disposed on the additional passivation layer 219 and exposes ends of the first connection electrode CE1 and the additional passivation layer 219 at an upper surface of the second planarization layer 317b, and an end of the first connection electrode CE1 at the upper surface of the second planarization layer 317b is covered by the organic pattern OP. Therefore, the organic pattern OP may cover an end of the first connection electrode CE1 disposed in a space between the additional passivation layer 219 and the light emitting element LED.

For example, the organic pattern OP may be simultaneously formed of the same material as the second planarization layer 317b. As described above, the second planarization layer 317b may be formed by disposing the second planarization material layer on the entire surface of the substrate 110 and performing an ashing process to adjust the thickness of the second planarization material layer. At this time, the second planarization material layer is over-ashed so that the uppermost end of the second planarization layer 317b may be disposed lower than the uppermost end of the additional passivation layer 219. Accordingly, the ends of the additional passivation layer 219 and the first connection electrode CE1 may be exposed. Meanwhile, even in such a case, since a space exists between the additional passivation layer 219 and the light emitting element LED, the second planarization material layer partially remains in the space between the additional passivation layer 219 and the light emitting element LED, and thus the end of the first connection electrode CE1 disposed between the additional passivation layer 219 and the light emitting element LED may be covered. In other words, the organic pattern OP may be a portion remaining between the additional passivation layer 219 and the light emitting element LED during the process of forming the second planarization layer 317b. Therefore, the organic pattern OP may be disposed to be spaced apart from the second planarization layer 317b with the additional passivation layer 219 interposed therebetween, but is not limited thereto.

That is, even though the second planarization layer 317b is over-ashed so that the second planarization layer 317b does not cover the end of the first connection electrode CE1 exposed by the additional passivation layer 219, the organic pattern OP may fill the space between the additional passivation layer 219 and the light emitting element LED. Therefore, the organic pattern OP may cover the end of the first connection electrode CE1 disposed between the additional passivation layer 219 and the light emitting element LED to separate the first connection electrode CE1 and the second connection electrode CE2.

Meanwhile, as described above, the organic pattern OP may be formed of the same material as the second planarization layer 317b, but is not limited thereto, and may be formed of another material.

Meanwhile, since the second planarization layer 317b is over-ashed, a height of a top surface of the second planarization layer 317b may be lower than a height of a top surface of the organic pattern OP. Therefore, the height of the uppermost end of the second planarization layer 317b may be lower than the height of the uppermost end of the organic pattern OP, but is not limited thereto.

The second connection electrode CE2 may be disposed on the second planarization layer 317b. Since the second planarization layer 317b is disposed to expose the additional passivation layer 219, the second connection electrode CE2 disposed on the second planarization layer 317b may be in contact with at least a portion of the additional passivation layer 219. For example, the second connection electrode CE2 may be in contact with an end of the additional passivation layer 219 exposed by the second planarization layer 317b, but is not limited thereto.

In the display device 300 according to still another example embodiment of the present disclosure, the additional passivation layer 219 may be disposed on the first connection electrode CE1 so as to cover at least a part of the first connection electrode CE1. Therefore, the additional passivation layer 219 may allow the first connection electrode CE1 and the second connection electrode CE2 to be separated from each other together with the second planarization layer 317b. Accordingly, the additional passivation layer 219 may prevent or suppress a short circuit between the first connection electrode CE1 and the second connection electrode CE2.

In addition, since the additional passivation layer 219 is formed of an inorganic insulating material, moisture or impurities penetrating into the plurality of first connection electrodes CE1 and the plurality of reflective electrodes RE connected thereto may be blocked. Accordingly, lifting of the plurality of reflective electrodes RE by moisture penetration and corrosion may be prevented or suppressed.

Specifically, in the display device 300 according to still another example embodiment of the present disclosure, even though the second planarization layer 317b is over-ashed to cover the first connection electrode CE1 exposed by the additional passivation layer 219, the organic pattern OP may cover the first connection electrode CE1 exposed by the additional passivation layer 219 to separate the first connection electrode CE1 and the second connection electrode CE2. For example, a portion of the first connection electrode CE1 exposed by the additional passivation layer 219 by the wet etching process as well as a portion overlapping the additional passivation layer 219 may be partially removed. Therefore, the height of the uppermost end of the end of the first connection electrode CE1 may be formed to be lower than the height of the uppermost end of the additional passivation layer 219. That is, the first connection electrode CE1 disposed between the additional passivation layer 219 and the light emitting element LED is partially removed so that a space may be formed between the additional passivation layer 219 and the light emitting element LED. Therefore, during the process of forming the second planarization layer 317b, the organic pattern OP may remain in the space between the additional passivation layer 219 and the light emitting element LED. In other words, even if the second planarization layer 317b is over-ashed, a space exists between the additional passivation layer 219 and the light emitting element LED so that during the process of forming the second planarization layer 317b, the organic pattern OP remains in the space between the additional passivation layer 219 and the light emitting element LED. Therefore, the organic pattern OP may cover an end of the first connection electrode CE1 disposed between the additional passivation layer 219 and the light emitting element LED by filling a space between the additional passivation layer 219 and the light emitting element LED. Accordingly, the first connection electrode CE1 and the second connection electrode CE2 may be separated. Therefore, the short defect of the first connection electrode CE1 and the second connection electrode CE2 may be minimized or reduced.

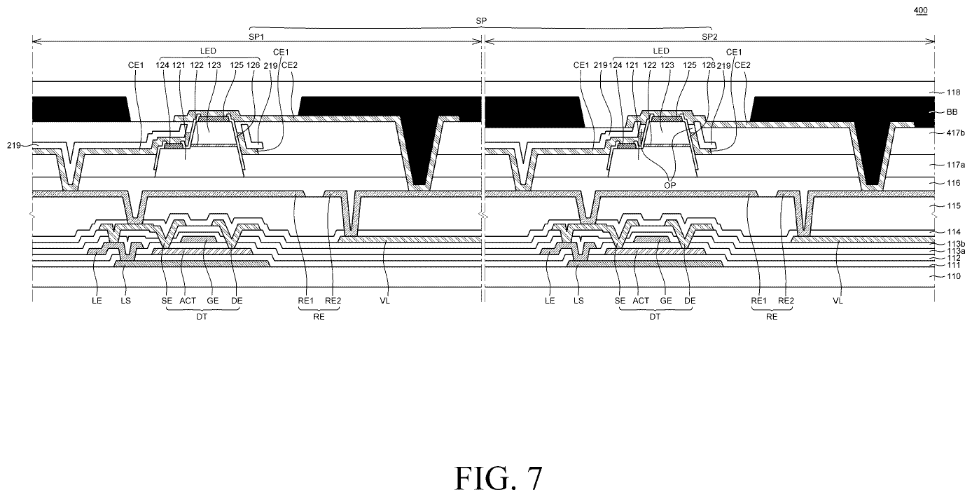

FIG. 7 is a cross-sectional view of a display device according to still another example embodiment of the present disclosure. FIG. 7 is a view for explaining a structure in which the second planarization layer 417b or the organic pattern OP is disposed to cover the first connection electrode CE1 so that the first connection electrode CE1 and the second connection electrode CE2 are separated even though the height of the second planarization layer 417b is different between the sub pixels SP. The structure of the first sub pixel SP1 of the display device 400 of FIG. 7 is substantially the same as the structure of the display device 200 of FIG. 5, and the structure of the second sub pixel SP2 is substantially the same as the structure of the display device 300 of FIG. 6, so that a redundant description will be omitted.

As shown in FIG. 7, the plurality of sub pixels SP may include a first sub pixel SP1 and a second sub pixel SP2 disposed in different areas. The first sub pixel SP1 and the second sub pixel SP2 may emit light of different colors or light of the same color.

In each sub pixel SP, a second planarization layer 417b may be disposed on the additional passivation layer 219. In this case, the height of the second planarization layer 417b may be different in the first sub pixel SP1 and the second sub pixel SP2. For example, a height of the second planarization layer 417b disposed in the second sub pixel SP2 may be lower than a height of the second planarization layer 417b disposed in the first sub pixel SP1. For example, the second planarization layer 417b may be formed at the same time in the first sub pixel SP1 and the second sub pixel SP2. However, due to the process error, the second planarization layer 417b may be over-ashed in the second sub pixel SP2 so that the height of the second planarization layer 417b may be formed to be lower in the second sub pixel SP2 than in the first sub pixel SP1.

For example, in the first sub pixel SP1, the second planarization layer 417b covers the first connection electrode CE1 exposed by the additional passivation layer 219 to separate the first connection electrode CE1 and the second connection electrode CE2.

Specifically, the second planarization layer 417b may be disposed to fill a space between the additional passivation layer 219 described above and the light emitting element LED. Accordingly, the second planarization layer 417b may cover the end of the first connection electrode CE1 disposed in the space between the additional passivation layer 219 and the light emitting element LED.

Meanwhile, because the second planarization layer 417b is disposed on the additional passivation layer 219, the second planarization layer 417b may be disposed to cover not only the first connection electrode CE1 exposed by the additional passivation layer 219, but also the additional passivation layer 219. In other words, the second planarization layer 417b may be disposed to cover the end of the first connection electrode CE1 disposed to surround a part of the side surface of the light emitting element LED and the end of the additional passivation layer 219 adjacent thereto. Therefore, the height of the top surface of the second planarization layer 417b may be higher than the height of each of the top ends of the first connection electrode CE1 and the additional passivation layer 219, but is not limited thereto.

Meanwhile, in the first sub pixel SP1, the second planarization layer 417b is disposed to cover the additional passivation layer 219. Therefore, the second connection electrode CE2 disposed on the second planarization layer 417b may be disposed to be spaced apart from the additional passivation layer 219, but is not limited thereto.

In the second sub pixel SP2, the second planarization layer 417b is over-ashed so that the height of the uppermost end of the second planarization layer 417b may be lower than the height of the uppermost end of the additional passivation layer 219. Accordingly, the second planarization layer 417b may expose an end of the additional passivation layer 219 disposed on the side surface of the light emitting element LED. That is, the second planarization layer 417b exposes the end of the additional passivation layer 219 so that the end of the first connection electrode CE1 exposed by the additional passivation layer 219 may be exposed.

In other words, the second planarization layer 417b may be disposed to expose an end of the first connection electrode CE1 disposed to surround a part of the side surface of the light emitting element LED and an end of the additional passivation layer 219 adjacent thereto, but is not limited thereto.

In the second sub pixel SP2, the organic pattern OP may be disposed to cover the end of the first connection electrode CE1 exposed by the additional passivation layer 219, such that the first connection electrode CE1 and the second connection electrode CE2 may be separated from each other.

Specifically, the organic pattern OP may be disposed to fill a space between the additional passivation layer 219 and the light emitting element LED. For example, the first connection electrode CE1 is disposed on the first planarization layer 117a and the side surfaces of the light emitting element LED, the additional passivation layer 219 is disposed on the first connection electrode CE1 and exposes ends of the first connection electrode CE1, the second planarization layer 417b is disposed on the additional passivation layer 219 and exposes ends of the first connection electrode CE1 and the additional passivation layer 219 at an upper surface of the second planarization layer 417b, and an end of the first connection electrode CE1 at the upper surface of the second planarization layer 417b is covered by the organic pattern OP. Therefore, the organic pattern OP may cover an end of the first connection electrode CE1 disposed in a space between the additional passivation layer 219 and the light emitting element LED. For example, the organic pattern OP may be a portion remaining between the additional passivation layer 219 and the light emitting element LED during the process of forming the second planarization layer 417b. Therefore, the organic pattern OP may be disposed to be spaced apart from the second planarization layer 417b with the additional passivation layer 219 interposed therebetween, but is not limited thereto.

That is, even though the second planarization layer 417b is over-ashed so that the second planarization layer 417b does not cover the end of the first connection electrode CE1 exposed by the additional passivation layer 219, the organic pattern OP may fill the space between the additional passivation layer 219 and the light emitting element LED. Therefore, the organic pattern OP may cover the end of the first connection electrode CE1 disposed between the additional passivation layer 219 and the light emitting element LED to separate the first connection electrode CE1 and the second connection electrode CE2.

Meanwhile, in the second sub pixel SP2, the second planarization layer 417b is over-ashed so that the height of the top surface of the second planarization layer 417b may be lower than the height of the top surface of the organic pattern OP. Therefore, the height of the uppermost end of the second planarization layer 417b may be lower than the height of the uppermost end of the organic pattern OP, but is not limited thereto and may be equal to the height of the uppermost end of the second planarization layer 417b.

That is, even though the second planarization layer 417b is formed to have a different ashing degree of the second planarization layer 417b in the first sub pixel SP1 and the second sub pixel SP2, the space between the additional passivation layer 219 and the light emitting element LED may be filled by the second planarization layer 417b in the first sub pixel SP1, and the organic pattern OP is filled in the second sub pixel SP2, the end of the first connection electrode CE1 disposed between the additional passivation layer 219 and the light emitting element LED may be covered to separate the first connection electrode CE1 and the second connection electrode CE2.

Meanwhile, in the second sub pixel SP2, the second planarization layer 417b is disposed to expose the additional passivation layer 219 so that the second connection electrode CE2 disposed on the second planarization layer 417b may be in contact with at least a portion of the additional passivation layer 219. For example, the second connection electrode CE2 may be in contact with an end of the additional passivation layer 219 exposed by the second planarization layer 417b, but is not limited thereto.

In the display device 400 according to still another example embodiment of the present disclosure, an additional passivation layer 219 may be disposed on the first connection electrode CE1 so as to cover at least a part of the first connection electrode CE1. Therefore, the additional passivation layer 219 may allow the first connection electrode CE1 and the second connection electrode CE2 to be separated from each other together with the second planarization layer 417b. Accordingly, the additional passivation layer 219 may prevent or suppress a short circuit between the first connection electrode CE1 and the second connection electrode CE2.

In addition, since the additional passivation layer 219 is formed of an inorganic insulating material, moisture or impurities penetrating into the plurality of first connection electrodes CE1 and the plurality of reflective electrodes RE connected thereto may be blocked. Accordingly, lifting of the plurality of reflective electrodes RE by moisture penetration and corrosion may be prevented or suppressed.

Specifically, in the display device 400 according to still another example embodiment of the present disclosure, the second planarization layer 417b covers the first connection electrode CE1 exposed by the additional passivation layer 219 in at least some sub pixels SP to separate the first connection electrode CE1 and the second connection electrode CE2. For example, a portion of the first connection electrode CE1 exposed by the additional passivation layer 219 by the wet etching process as well as a portion overlapping the additional passivation layer 219 may be partially removed. Therefore, the height of the uppermost end of the end of the first connection electrode CE1 may be formed to be lower than the height of the uppermost end of the additional passivation layer 219. That is, the first connection electrode CE1 disposed between the additional passivation layer 219 and the light emitting element LED is partially removed so that a space may be formed between the additional passivation layer 219 and the light emitting element LED. Accordingly, the second planarization layer 417b disposed on the additional passivation layer 219 may fill a space between the additional passivation layer 219 and the light emitting element LED to cover the end of the first connection electrode CE1 disposed between the additional passivation layer 219 and the light emitting element LED. Accordingly, the first connection electrode CE1 and the second connection electrode CE2 disposed on the second planarization layer 417b may be separated. Therefore, the short defect of the first connection electrode CE1 and the second connection electrode CE2 may be minimized or reduced.

Specifically, in the display device 400 according to still another example embodiment of the present disclosure, even though the second planarization layer 417b is excessively ashed in some sub pixels SP to not cover the first connection electrode CE1 exposed by the additional passivation layer 219, the organic pattern OP may cover the first connection electrode CE1 exposed by the additional passivation layer 219 to separate the first connection electrode CE1 and the second connection electrode CE2. As described above, the first connection electrode CE1 disposed between the additional passivation layer 219 and the light emitting element LED is partially removed so that a space is formed between the additional passivation layer 219 and the light emitting element LED. Therefore, during the process of forming the second planarization layer 417b, the organic pattern OP may remain in the space between the additional passivation layer 219 and the light emitting element LED. In other words, even if the second planarization layer 417b is over-ashed, a space exists between the additional passivation layer 219 and the light emitting element LED so that during the process of forming the second planarization layer 417b, the organic pattern OP remains in the space between the additional passivation layer 219 and the light emitting element LED. Therefore, the organic pattern OP may cover an end of the first connection electrode CE1 disposed between the additional passivation layer 219 and the light emitting element LED by filling a space between the additional passivation layer 219 and the light emitting element LED. Accordingly, the first connection electrode CE1 and the second connection electrode CE1 may be separated. Therefore, the short defect of the first connection electrode CE1 and the second connection electrode CE2 may be minimized or reduced.

The example embodiments of the present disclosure can also be described as follows:

According to an example embodiment of the present disclosure, a display device includes a substrate in which a plurality of sub pixels are defined, a plurality of light emitting elements which are disposed on the substrate in the plurality of sub pixels and each includes a first electrode and a second electrode, a first planarization layer which is disposed on the substrate so as to surround a part of side surfaces of the plurality of light emitting elements, a first connection electrode which is disposed on the first planarization layer and is electrically connected to the first electrode, a passivation layer disposed on the first connection electrode, a part of the passivation layer, a second planarization layer disposed on the first planarization layer and the first connection electrode, and a second connection electrode which is disposed on the second planarization layer and is electrically connected to the second electrode, the passivation layer exposes an end of the first connection electrode.

According to another aspect of the present disclosure, the height of the uppermost end of the end of the first connection electrode may be lower than the height of the uppermost end of the passivation layer.

According to yet another aspect of the present disclosure, the second planarization layer may cover the end of the first connection electrode exposed by the passivation layer.

According to yet another aspect of the present disclosure, the second planarization layer may be disposed to cover the end of the first connection electrode and an end of the passivation layer disposed to surround the part of side surfaces of the plurality of light emitting elements.

The second connection electrode may be disposed to be spaced apart from the passivation layer.

According to yet another aspect of the present disclosure, the second planarization layer may fill a space between the plurality of light emitting elements and the passivation layer.

According to yet another aspect of the present disclosure, the second planarization layer may expose an end of the passivation layer disposed to surround the part of side surfaces of the plurality of light emitting elements.

According to yet another aspect of the present disclosure, the display device may further comprise an organic pattern disposed between the passivation layer and the plurality of light emitting elements and disposed to cover the end of the first connection electrode disposed to surround the part of side surfaces of the plurality of light emitting elements.

According to yet another aspect of the present disclosure, the organic pattern may cover the end of the first connection electrode exposed by the passivation layer.

According to yet another aspect of the present disclosure, the organic pattern may be disposed to be spaced apart from the second planarization layer with the passivation layer interposed therebetween.

According to yet another aspect of the present disclosure, the height of the top surface of the second planarization layer may be lower than the height of the top surface of the organic pattern.

According to yet another aspect of the present disclosure, the second connection electrode may be disposed to contact at least a portion of the passivation layer.

According to yet another aspect of the present disclosure, the second connection electrode may be in contact with the end of the passivation layer exposed by the second planarization layer.

According to yet another aspect of the present disclosure, the display device may further an organic pattern. In some sub pixels among the plurality of sub pixels, the second planarization layer may further include an organic pattern disposed to cover an end of the first connection electrode and an end of the passivation layer disposed to surround the part of a side surface of the plurality of light emitting elements. In some other sub pixel among the plurality of sub pixels, the organic pattern disposed to cover the end of the first connection electrode disposed to surround the part of a side surface of the plurality of light emitting elements. In some other sub pixel among the plurality of sub pixels, the second planarization layer may be spaced apart with the organic pattern and the passivation layer interposed therebetween, and may expose the end of the passivation layer disposed to surround the part of a side surface of the plurality of light emitting elements.

According to an another embodiment of the present disclosure, a display device comprises a substrate in which a plurality of sub pixels are defined, a plurality of light emitting elements which are disposed on the substrate in the plurality of sub pixels and each includes a first electrode and a second electrode disposed at a position higher than the first electrode, a first planarization layer which is disposed on the substrate so as to surround a part of side surfaces of the plurality of light emitting elements, a first connection electrode which is disposed on the first planarization layer and is electrically connected to the first electrode, a second planarization layer disposed on the first planarization layer and the first connection electrode, and a second connection electrode which is disposed on the second planarization layer and is electrically connected to the second electrode.

According to another aspect of the present disclosure, the display device may further comprise a passivation layer disposed between the first connection electrode and the second planarization layer. The passivation layer may be disposed to surround the part of side surfaces of the plurality of light emitting elements and expose an end of the first connection electrode disposed on the side surfaces of the plurality of light emitting elements.

According to yet another aspect of the present disclosure, the second planarization layer may be disposed to cover the end of the first connection electrode exposed by the passivation layer.

According to yet another aspect of the present disclosure, the height of the top surface of the second planarization layer may be higher than the height of the uppermost end of the passivation layer. The second planarization layer may be disposed to cover the end of the passivation layer adjacent to the end of the first connection electrode.

According to yet another aspect of the present disclosure, the display device may further include an organic pattern disposed between the passivation layer and the plurality of light emitting elements and disposed to cover the end of the first connection electrode exposed by the passivation layer. The second planarization layer may be disposed to be spaced apart from the organic pattern with the passivation layer interposed therebetween, and may expose an end of the passivation layer adjacent to an end of the first connection electrode.

According to yet another aspect of the present disclosure, a height of an uppermost end of the second planarization layer may be lower than a height of an uppermost end of the organic pattern and a height of an uppermost end of the passivation layer, respectively.

According to yet another aspect of the present disclosure, a display device includes a substrate in which a plurality of sub pixels are defined; a plurality of light emitting elements which are disposed on the substrate in the plurality of sub pixels and each includes a first electrode and a second electrode; a first planarization layer which is disposed on the substrate so as to surround a part of side surfaces of the plurality of light emitting elements; a first connection electrode which is disposed on the first planarization layer and is electrically connected to the first electrode; a passivation layer which is disposed on the first connection electrode; a second planarization layer which is disposed on the first planarization layer, the first connection electrode, and at least a part of the passivation layer; and a second connection electrode which is disposed on the second planarization layer and is electrically connected to the second electrode, wherein the passivation layer exposes an end of the first connection electrode, the plurality of sub pixels includes a first sub pixel and a second sub pixel disposed in different area of the substrate and a height of an uppermost end of the second planarization layer disposed in the second sub pixel is lower than a height of an uppermost end of the second planarization layer disposed in the first sub pixel.

According to yet another aspect of the present disclosure, in the second sub pixel, the height of an uppermost end of the second planarization layer is lower than a height of an uppermost end of the passivation layer, and in the first sub pixel, the height of an uppermost end of the second planarization layer is high than a height of an uppermost end of the passivation layer.

According to yet another aspect of the present disclosure, in the second sub pixel, an organic pattern is disposed between the passivation layer and the plurality of light emitting elements, the organic pattern being disposed to cover an end of the first connection electrode disposed to surround the part of side surfaces of the plurality of light emitting elements.

According to yet another aspect of the present disclosure, in in the second sub pixel, the height of an uppermost end of the second planarization layer is lower than a height of an uppermost end of the passivation layer and the height of an uppermost end of the organic pattern, and in the first sub pixel, a height of an uppermost end of the second planarization layer is high than a height of an uppermost end of the passivation layer.

According to yet another aspect of the present disclosure, a display panel includes a substrate in which a plurality of sub pixels are defined; a plurality of light emitting elements which are disposed on the substrate in the plurality of sub pixels and each includes a first electrode and a second electrode; a first planarization layer which is disposed on the substrate so as to surround a part of side surfaces of the plurality of light emitting elements; a first connection electrode which is disposed on the first planarization layer and is electrically connected to the first electrode; a passivation layer which is disposed on the first connection electrode; a second planarization layer which is disposed on the first planarization layer, the first connection electrode, and a part of the passivation layer; and a second connection electrode which is disposed on the second planarization layer and is electrically connected to the second electrode, wherein the passivation layer exposes an end of the first connection electrode.

According to yet another aspect of the present disclosure, a display panel includes a substrate in which a plurality of sub pixels are defined; a plurality of light emitting elements which are disposed on the substrate in the plurality of sub pixels, and each includes a first electrode and a second electrode disposed at a position higher than the first electrode; a first planarization layer which is disposed on the substrate so as to surround a part of side surfaces of the plurality of light emitting elements; a first connection electrode which is disposed on the first planarization layer and is electrically connected to the first electrode; a second planarization layer disposed on the first planarization layer and the first connection electrode; and a second connection electrode which is disposed on the second planarization layer and is electrically connected to the second electrode.

According to yet another aspect of the present disclosure, a display panel includes a substrate in which a plurality of sub pixels are defined; a plurality of light emitting elements which are disposed on the substrate in the plurality of sub pixels and each includes a first electrode and a second electrode; a first planarization layer which is disposed on the substrate so as to surround a part of side surfaces of the plurality of light emitting elements; a first connection electrode which is disposed on the first planarization layer and is electrically connected to the first electrode; a passivation layer which is disposed on the first connection electrode; a second planarization layer which is disposed on the first planarization layer, the first connection electrode, and at least a part of the passivation layer; and a second connection electrode which is disposed on the second planarization layer and is electrically connected to the second electrode, wherein the passivation layer exposes an end of the first connection electrode, the plurality of sub pixels includes a first sub pixel and a second sub pixel disposed in different area of the substrate and a height of an uppermost end of the second planarization layer disposed in the second sub pixel is lower than a height of an uppermost end of the second planarization layer disposed in the first sub pixel.

Although the example embodiments of the present disclosure have been described in detail with reference to the accompanying drawings, the present disclosure is not limited thereto and may be embodied in various forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all embodiments and do not limit the present disclosure.

What is claimed is:

1. A display device comprising:
a substrate in which a plurality of sub pixels are defined;
a plurality of light emitting elements which are disposed on the substrate in the plurality of sub pixels, each including a first electrode and a second electrode;
a first planarization layer which is disposed on the substrate so as to surround a part of side surfaces of the plurality of light emitting elements;
a first connection electrode which is disposed on the first planarization layer and is electrically connected to the first electrode;
a passivation layer which is disposed on the first connection electrode;
a second planarization layer which is disposed on the first planarization layer, the first connection electrode, and a part of the passivation layer; and
a second connection electrode which is disposed on the second planarization layer and is electrically connected to the second electrode,
wherein the passivation layer exposes an end of the first connection electrode.

2. The display device according to claim 1, wherein a height of an uppermost end of the end of the first connection electrode is lower than a height of an uppermost end of the passivation layer.

3. The display device according to claim 1, wherein the second planarization layer covers the end of the first connection electrode exposed by the passivation layer.

4. The display device according to claim 3, wherein the second planarization layer is disposed so as to cover the end of the first connection electrode and an end of the passivation layer which are disposed so as to surround the part of side surfaces of the plurality of light emitting elements.

5. The display device according to claim 4, wherein the second connection electrode is disposed to be spaced apart from the passivation layer.

6. The display device according to claim 1, wherein the second planarization layer is filled in a space between the plurality of light emitting elements and the passivation layer.

7. The display device according to claim 1, wherein the second planarization layer exposes an end of the passivation layer disposed so as to surround the part of side surfaces of the plurality of light emitting elements.

8. The display device according to claim 7, further comprising:
an organic pattern disposed between the passivation layer and the plurality of light emitting elements and disposed to cover the end of the first connection electrode disposed to surround the part of side surfaces of the plurality of light emitting elements.

9. The display device according to claim 8, wherein the organic pattern covers the end of the first connection electrode exposed by the passivation layer.

10. The display device according to claim 8, wherein the organic pattern is disposed to be spaced apart from the second planarization layer with the passivation layer interposed therebetween.

11. The display device according to claim 8, wherein a height of a top surface of the second planarization layer is lower than a height of a top surface of the organic pattern.

12. The display device according to claim 7, wherein the second connection electrode is disposed to be in contact with at least the part of the passivation layer.

13. The display device according to claim 12, wherein the second connection electrode contacts an end of the passivation layer exposed by the second planarization layer.

14. The display device according to claim 1, further comprising:
an organic pattern,
wherein:
in some sub pixels among the plurality of sub pixels, the second planarization layer is disposed to cover the end of the first connection electrode and an end of the passivation layer which are disposed to surround the part of side surfaces of the plurality of light emitting elements;
in some other sub pixels among the plurality of sub pixels, the organic pattern is disposed to cover the end of the first connection electrode disposed to surround the part of the side surfaces of the plurality of light emitting elements; and
in the some other sub pixels among the plurality of sub pixels, the second planarization layer is disposed to be spaced apart from the organic pattern with the passivation layer interposed therebetween and exposes the end of the passivation layer disposed to surround the part of the side surfaces of the plurality of light emitting elements.

15. A display device, comprising:
a substrate in which a plurality of sub pixels are defined;
a plurality of light emitting elements which are disposed on the substrate in the plurality of sub pixels and include a first electrode and a second electrode disposed at a position higher than the first electrode;
a first planarization layer which is disposed on the substrate so as to surround a part of side surfaces of the plurality of light emitting elements;
a first connection electrode which is disposed on the first planarization layer and is electrically connected to the first electrode;
a second planarization layer disposed on the first planarization layer and the first connection electrode; and
a second connection electrode which is disposed on the second planarization layer and is electrically connected to the second electrode.

16. The display device according to claim 15, further comprising:
a passivation layer disposed between the first connection electrode and the second planarization layer,
wherein the passivation layer is disposed so as to surround the part of side surfaces of the plurality of light emitting elements and exposes an end of the first connection electrode disposed on the side surfaces of the plurality of light emitting elements.

17. The display device according to claim 16, wherein the second planarization layer is disposed to cover the end of the first connection electrode exposed by the passivation layer.

18. The display device according to claim 17, wherein:
a height of a top surface of the second planarization layer is higher than a height of an uppermost end of the passivation layer; and
the second planarization layer is disposed to cover an end of the passivation layer adjacent to the end of the first connection electrode.

19. The display device according to claim 16, further comprising:
an organic pattern disposed between the passivation layer and the plurality of light emitting elements and disposed to cover the end of the first connection electrode exposed by the passivation layer,
wherein the second planarization layer is disposed to be spaced apart from the organic pattern with the passivation layer interposed therebetween and exposes an end of the passivation layer adjacent to the end of the first connection electrode.

20. The display device according to claim 19, wherein a height of an uppermost end of the second planarization layer is lower than a height of each of an uppermost end of the organic pattern and an uppermost end of the passivation layer, respectively.
